(19) United States
(12) Patent Application Publication
(10) Pub. No.: US 2012/0164564 A1
(43) Pub. Date: Jun. 28, 2012

(54) ADVANCED PHOTOMASK REPAIR

(75) Inventors: Nabil Amro, Chicago, IL (US); Raymond Sanedrin, Evanston, IL (US); Sandeep Disawal, Chicago, IL (US); Joseph S. Fragala, San Jose, CA (US)

(73) Assignee: NanoInk, Inc.

(21) Appl. No.: 13/381,590

(22) PCT Filed: Jun. 29, 2010
(86) PCT No.: PCT/US10/40470

§ 371 Date: Mar. 12, 2012

Related U.S. Application Data
(60) Provisional application No. 61/222,096, filed on Jun. 30, 2009.

(51) Int. Cl. G03F 1/72; C08K 5/07; C08J 3/28; C08K 5/05; C08K 5/20; C08K 5/053; C08K 5/057; C09D 183/00

(52) U.S. Cl. 430/5; 524/382; 524/357; 524/588; 524/385; 524/233; 524/386; 524/361; 522/172

(57) ABSTRACT

Additive repair of advanced photomasks with low temperature or optical curing via direct write lithographic printing with sharp tips and cantilevers. The optical properties of the materials formed from the ink can be tuned (e.g., n and k values). Sol gel inks, including silsesquioxane inks, can be used to form MoSi compositions. The repaired photomasks are resistant to washing under normal photomask washing conditions. AFM instrumentation can be used to perform the additive repair to provide the high resolution and registration.

### BACKGROUND

Photomasks are widely used in the semiconductor industry to prepare, for example, integrated circuits. Masks are typically expensive and complex and are becoming more sophisticated with smaller feature sizes each year. Hence, if a mask is defective, an economic need is present to repair the mask rather than merely dispose of it. Hence, a commercial need exists to find better methods to repair photomasks. In particular, additive repair is important, wherein material is added to the mask. In subtractive repair, material is taken away from the mask. An important problem in additive repair is tuning the ink formulation to provide the correct optical properties including transparency and refractive index. In addition, if the ink requires curing, suitable curing conditions are needed which are compatible with photomask repair. These problems become particularly important when dealing with advanced and next generation photomasks including those with high resolution structures with complex depressions and protrusions.

Many current mask repair technologies, which include laser-induced or electron-beam-induced deposition or etching and focused ion beam (FIB), lack the resolution and material flexibility required to repair advanced photomasks and can damage the masks while repairing them. The problem can be especially severe while additively repairing quartz pits and other voids in the substrate of advanced photomasks and attenuation layer (the so-called ‘MoSi’ layer, typically a MoₓSi_{y}O_{z}Nₜ graded film) of attenuated phase-shift masks, due to the lack of a technology capable of depositing a transparent or semi-transparent material with controlled optical properties and nanoscale registration. Opaque carbon patches have been deposited (e.g. by FIB) on phase-shift masks in an attempt to repair them, but with minimal control over the resulting aerial image during exposure.

U.S. Patent Publication Number 2004/0175631 (NanoInk), which is incorporated herein by reference in its entirety, describes additive photomask repair methods including use of direct-write nanolithography and nanoscopic tips. Photomask repair is also briefly noted in U.S. Patent Publication Number 2005/0255237 to Zhang et al. (NanoInk), which is incorporated herein by reference in its entirety, including stamp tip methods of repair. In addition, U.S. Patent Publication Number 2003/0162004 to Mirkin et al. (Northwestern University), which is incorporated herein by reference in its entirety, describes use of sol-gel inks and direct write nanolithography. However, photomask repair is not described. Thermal cure of inks is described including working examples wherein thermal cure is executed at 400° C. In addition, polymers are used in the sol-gel formulation.

Additional references, all of which are incorporated herein by reference in their entirety, relating to thin films and repair materials, include: “Ultraviolet laser-induced formation of thin silicon dioxide film from the precursor beta-chloroethyl silsesquioxane” J. Sharma, et al., J. Mater. Res. 14(3), 990, 1999; “High Density Silicon Dioxide Coatings by UV and Thermal Processing” B. Arkles, et al. Silicones in Coatings III meeting proceedings, Barcelona (Spain), 28-30 Mar. 2000 (available from Gelest, Inc.); “Characterization of optically active and photocurable ORMOSIL thin films deposited using the Aerosol process” M. Trejo-Valdez, P. et al. J. Mater. Sci. 39, 2801-2810, 2004; “Photo-induced growth of dielectrics with excimer lamps”, I. W. Boyd, et al., Solid-State Electronics 45, 1413-1431, 2001; “Patterning of hybrid titania film using polypolymerization”, H. Segawa, et al., Thin Solid Films 466, 48-53, 2004; “Sol-gel fabrication of high-quality photomask substrates”, R. Ganguli, et al. Microlith. Microfab. Microsyst. 2(3), 2003; “Photosensitive gel films prepared by the chemical modification and their application to surface-relief gratings”, N. Tohge, et al., Thin Solid Films 351, 85-90, 1999; “Structural and electrical characteristics of zirconium oxide layers derived from photo-assisted sol-gel processing”, J. J. Wu, et al., Appl. Phys. A 74, 143-146, 2002; “Composite thin films of (ZrO₂)ₓ—(Al₂O₃)₁₋ₓ for high transmittance attenuated phase shifting mask in ArF optical lithography”, F.-D. Lai J. Vac. Sci. Technol. B 22(3), 1174, 2004; and “Low temperature elimination of organic components from mesostructured organic-inorganic composite films using vacuum ultraviolet light”, A. Hozumi, et al., Chem. Mater. 12, 3842-3847, 2000.

### SUMMARY

Optically tunable inks and methods of using them, as well as devices and cured materials, are provided for advanced photomask repair and other applications for which optical tuning is important. In particular, in one embodiment, presently provided is a method for repairing a photomask, including: providing a nanoscopic tip comprising an ink disposed on the tip end, wherein the ink is formulated for curing at temperatures of about 100° C. to about 350° C.; providing a photomask comprising region which needs to be repaired; contacting the tip with the photomask in the region which needs to be repaired, wherein ink is transferred from the tip to the region; forming a cured ink by (i) heating the ink at a temperature of about 100° C. to about 350° C., and/or (ii) exposing the ink to electromagnetic radiation.

One embodiment also provides a sol-gel composition formed by mixing: a silicon dioxide precursor compound; and a molybdenum precursor composition formed by evaporating a polar protic solvent out of a solution comprising the polar protic solvent and a molybdenum compound.

In an embodiment, the ink can be a sol-gel composition formed by mixing a carrier solvent, a silicon dioxide precursor, and a molybdenum precursor. The silicon dioxide precursor can be a silsesquioxane, such as poly(2-chloroethyl)silsesquioxane, or other silsesquioxane compounds. The molybdenum precursor can be formed by evaporating a polar protic solvent out of a solution containing the polar protic solvent and at least one of molybdenum(V) ethoxide, or molybdenum(VI) oxide Bis(2,4-pentanedionate), or MoₓL_{y} (where L=organic molecule or ligand). The polar protic solvent can have a molecular weight that is preferably less than 70 g/mol, such as less than 60 g/mol, and more specifically less than 50 g/mol. For example, the polar protic solvent can be ethanol (46.1 g/mol).

Advantages for at least some embodiments include, for example, high resolution repair, good spatial registration, ability to repair without inducing additional damage, ability to optically tune the ink to solve a particular problem, good adhesion of the cured ink to the substrate, low contamination levels, ability to repair at bottom of deep depressions or apertures, and the film only comprising of (or consisting essentially of) metal, silicon, and oxygen and in some cases addition of nitrogen. Additional advantages for at least some embodiments include: precise control over the properties of the material being deposited; low toxicity of the chemicals involved; low risk of chemical contamination of the whole photomask during the repair process; simple instrumentation; operation of the equipment in ambient atmosphere as opposed to vacuum; high accuracy and precision (e.g. 10 nm placement accuracy); ability to deposit a large variety of new materials; no transmission loss due to substrate staining, no mask damage during imaging (allowing a large number of repair cycles); ability to repair clear and opaque defects in the same tool; compatibility with all mask types and materials, including quartz, molybdenum silicide, Mo/Si multilayers and tantalum nitride films; and multi-node capabilities.

Additional features for at least some embodiments include, for example, the ability to tune the optical properties of the cured ink to match the optical properties of the photomask. Tuning of optical properties can be accomplished, for example, by controlling the presence of molybdenum and silicon dioxide in the MoSi alloy. Tunable optical properties of the ink include, but are not limited to, the refractive index (n) and the extinction coefficient (k). Because the values of both n and k depend on the wavelength of incident light, these values for the cured ink should approximate those of the photomask at or around the wavelengths used for lithographic exposure or photomask inspection. The overall transmittance, reflectance, and absorbance of the cured ink approximately matches that of the photomask. The cured ink is also mechanically and chemically stable, preferably adhering well to the photomask and stable to repeated washing and rinsing. The viscosity of the ink prior to curing can also be tuned, such as to provide greater or less viscosity depending on either the defect type and size, or the particular surface properties of the photomask.

### BRIEF DESCRIPTION OF THE DRAWINGS

FIG. 1A is a bottom schematic view of a photomask repair chip according to an embodiment of the present invention.

FIG. 1B is a side schematic view of a curing tip of the photomask repair chip of FIG. 1A.

FIG. 2A is an atomic force microscope (AFM) image of three simulated clear defects (approximately 200 nm deep, 300 nm×300 nm wide) of an alternating aperture phase shifting photomask (AAPSM). The middle defect is filled with a poly(2-chloroethyl)-silsesquioxane (PCESQ) sol gel ink using DPN® printing after thermal curing. FIG. 2B is a height profile along “Line 1” in FIG. 2A.

FIGS. 3A-3D and FIG. 4 are plots of measured refractive index (n) and extinction coefficient (k) versus wavelength measured using ellipsometry. FIG. 3A shows ellipsometry data for a MoSi thin film formed by chemical vapor deposition (CVD). FIG. 3B shows ellipsometry data for a cured ink containing 1:15 volumetric ratio of molybdenum(VI) oxide Bis(2,4-pentanedionate) to PCESQ. FIG. 3C shows ellipsometry data for a cured ink containing 1:4 volumetric ratio of molybdenum(VI) oxide Bis(2,4-pentanedionate) to PCESQ. FIG. 3D shows ellipsometry data for a cured ink containing 2.5:1 volumetric ratio of Mo(OCH₂CH₃)₅ to PCESQ.

FIG. 4 shows ellipsometry data for a cured ink containing 1:10 ratio by weight of Mo(OCH₂CH₃)₅ to PCESQ.

FIG. 5 is an AFM image (20 μm×20 μm) of a 3×3 array of MoSi microdots formed by curing an ink containing 1:5 volumetric ratio of Mo(V) ethoxide to PCESQ and 20 wt. % decanol deposited by DPN® printing.

FIGS. 6A-6C are plots of measured intensity versus binding energy measured using x-ray photoelectron spectroscopy (XPS). FIG. 6A shows an XPS spectrum for a MoSi film formed by heating at 200° C. an ink containing 1:4 ratio by weight of Mo(V) ethoxide to PCESQ and 20 wt. % decanol. FIG. 6B shows an XPS spectrum for an MoSi film formed by heating at 200° C. an ink containing 1:4 ratio by weight of Mo(V) ethoxide to PCESQ and 20 wt. % decanol and 6 wt. % tetrabutylammonium fluoride catalyst. FIG. 6C shows an XPS spectrum from an MoSi film formed by heating at 350° C. the ink of FIG. 6B. M represents Mo; S represents SiOx.

FIGS. 7A-7B are optical microscope images of 5×5 array of structures on a silicon substrate fabricated using an ink containing 1:4 volumetric ratio of Mo(V) ethoxide to PCESQ and 20 wt. % decanol and 6 wt. % tetrabutylammonium fluoride catalyst using DPN® printing.

FIGS. 8A-8B are AFM images of apertures in a photomask (6025 EAPSM) before and after filling with an ink containing 1:10 volumetric ratio of Mo(VI) oxide Bis(2,4-pentanedionate) to PCESQ using DPN® printing, respectively. Each simulated defect has a length and width of 2 μm and 0.6 μm, respectively.

FIGS. 9A-9B are two- and three-dimensional AFM images, respectively, of apertures after filling one of the apertures with an ink containing 1:10 weight ratio of Mo(VI) oxide Bis(2,4-pentanedionate) to PCESQ and 4:1 volumetric ratio of dimethylformamide to poly(ethyl)glycol using DPN® printing. FIG. 9C is a height profile along “Line 1” in FIG. 9A.

FIG. 10 shows a series of AFM images of a MoSi microdot array before and after three rounds of cleaning under the following conditions: 120 s in piranha (3:1 by volume H₂SO₄:H₂O₂) at 65° C., followed by sonication for 30 s at 20 watt/cm², followed by sonication for 30 s at 4 watt/cm², followed by 120 s DI rinse, followed by heating for 15 min at 100° C.

FIGS. 11A-11E show AFM images of a MoSi microdot array formed by depositing an ink formulation containing Mo(VI) oxide Bis(2,4-pentanedionate) and PCESQ using DPN® printing and photocuring by excimer laser irradiation.

FIG. 12 describes phase shift mask ink formulation.

FIG. 13 illustrates data for free standing PCESQ dot arrays on 6025 quartz mask.

FIG. 14 shows dot diameter size and optical image of free standing PCESQ on 6025 quartz mask.

FIG. 15 illustrates topographic AFM 2D and 3D images of MoSi film on quartz substrates.

FIG. 16 illustrates free standing MoSi Dot arrays on SiO₂ substrates.

FIG. 17 shows dot diameter size and optical image of free standing PCESQ on 6025 quartz mask.

FIG. 18 illustrates free standing MoSi dot arrays on quartz mask.

FIG. 19 illustrates varying deposition time of MoSi ink deposition in square recessed features.

FIG. 20 shows AFM and height contour plots of MoSi samples deposited and cured in defect areas.

FIG. 21 illustrates free standing MoSi dot arrays on SiO₂ substrate and MoSi deposited in defect areas.

FIG. 22 describes laser curing of MoSi films.

FIG. 23 illustrates XPS spectra of laser cured MoSi films.

FIG. 24 illustrates XPS spectra of uncured MoSi film.

FIG. 25 illustrates XPS data for cured SiOx films by excimer laser.

FIG. 26 illustrates excimer laser curing of free standing PCESQ dot features.

FIG. 27 illustrates excimer laser curing of free standing PCESQ dot features.

FIG. 28 illustrates gold coated AFM tip for ink deposition if difficulty encountered in depositing certain Mo inks for some embodiments.

FIG. 29 illustrates single and double deposition of Mo(V) PCSEQ ink in MoSi mask defect areas.

FIG. 30 illustrates deposition of Mo(V) PCSEQ ink on 6025 quartz mask.

FIG. 31 illustrates deposition of Mo(V) PCSEQ in MoSi mask defect areas.

FIG. 32 illustrates transmittance comparison between MoSi mask and MoSi film.

### DETAILED DESCRIPTION

Introduction/General

No admission is made that any reference cited herein is prior art. U.S. Pat. No. 6,635,311 to Mirkin et al. (“Methods Utilizing Scanning Probe Microscope Tips And Products Therefor Or Produced Thereby”), which is hereby incorporated by reference in its entirety, discloses a direct-write patterning method in which, for example, a sharp tip (e.g., a “pen”) coated with a chemical compound or mixture (e.g., an “ink”) is contacted with a substrate. With this method, commercialized under Dip Pen Nanolithography™ printing (“DPN® printing”), arbitrary patterns may be fabricated with sub-20 nm resolution, 10 nm feature alignment and a wide variety of inks, including but not limited to metal or ceramic precursors or nanoparticles can be used. The DPN® printing nanotechnology platform is commercialized by NanoInk, Inc. (Skokie, Ill.). DPN®, Dip Pen Nanolithography™, NanoInk® are its trademarks.

In addition, U.S. patent application Ser. No. 10/689,547 to Crocker et al, which is hereby incorporated by reference in its entirety, and in particular its Parts 6 and 7, teaches (i) the deposition of substantially optically transparent materials, for photomask repair application and (ii) the repair of advanced masks, such as phase-shift masks and NIL/SFIL molds, including the repair of voids in a transparent substrate with sol-gel deposition, and the repair of partially transmitting phase-shifting layers, e.g., by deposition of molybdenum oxide or silicide nanoparticle-loaded sol-gel materials.

One embodiment described herein provides a method for repairing a photomask comprising: providing a nanoscopic tip comprising an ink disposed on the tip end, wherein the ink is formulated for curing at temperatures of about 100° C. to about 350° C.; providing a photomask comprising region which needs to be repaired; contacting the tip with the photomask in the region which needs to be repaired, wherein ink is transferred from the tip to the region; and forming a cured ink by (i) heating the ink at a temperature of about 100° C. to about 350° C., and/or (ii) exposing the ink to electromagnetic radiation.

### Heating Cure Embodiment

One embodiment comprises a heating cure step. In this embodiment, ink cure is carried out either: (i) without a radiation exposure; or (ii) with a supplemental radiation exposure either before, during, or after the heating exposure. The heating step may be performed either on the entire photomask or on the localized repair region. Heat may be provided in any way that sufficiently raises the temperature of the ink to result in curing of the ink without damaging the photomask. For example, an oven or a hand-held heat gun may be used; or heating may be performed by electron or ion bombardment. Other heating methods, such as resistive heating within or around the photomask, can be readily used. Heating is performed at a temperature of about 100° C. to about 350° C., such as about 150° C. to about 250° C., such as about 250° C.

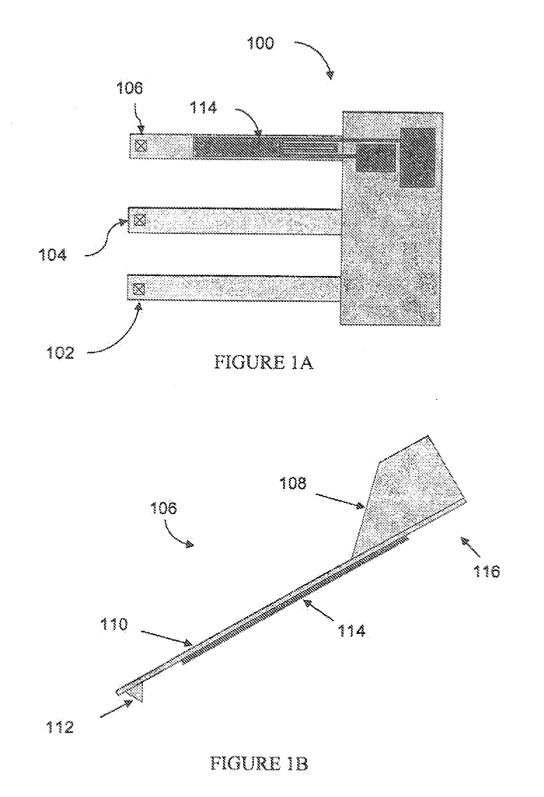

FIG. 1A shows an example of a photomask repair chip 100 that includes a reading tip 102 for locating a defect to be repaired, a writing tip 104 for depositing an ink in the defect area, and a curing tip 106 for curing the deposited ink. The reading tip 102 can also be used for subtractive repair, including removing excess ink from the photomask. Optionally, the reading tip 102 is not used for subtractive repair, but the photomask repair chip comprises a fourth tip (not shown in FIG. 1A) used for subtractive repair.

FIG. 1B shows the curing tip 106 of the repair chip 100. The curing tip 106 includes a substrate handle 108 that supports a cantilever 110, at the end of which is a pyramidal tip 112. A resistive heater 114 is disposed on the bottom surface of the cantilever 110. Alternatively, the resistive heater 114 can be located either on the top surface of the cantilever 110, or both top and bottom surfaces. Optionally, the resistive heater can be located only on or around the tip 112. In an embodiment, the heating cure step involves scanning the curing tip 106 over a photomask region that is in need of repair. The temperature of the resistive heater 114 can be controlled by varying the amount of current provided to the heater 114 through a wire 116 and/or by varying the resistivity of the heater 114, such as by changing the materials used in the heater 114. The curing conditions applied to the ink to be cured can be controlled by varying the scan rate of the curing tip 106 and/or by varying the distance between the photomask defect and the heater 114, such as by varying the dimensions of the pyramidal tip 112.

Other heating mechanisms can be used to cure the ink. For example, a pinpoint soldering gun which radiates heat at small distances, such as distances less than about 3 mm, can be brought into close proximity to the defect area, such as within a few microns above the defect area. The diameter of the tip of the solder gun can vary from about 1 mm to about 50 μm, such as about 100 μm. Alternatively, a resistive heating wire, such as a Nichrome-60 wire (or other wires), can be wrapped around a insulative tube, such as a ceramic tube, which can then be embedded in a concave shiny metallic apparatus to direct and reflect the generated heat from the wire onto the defect area. The localized heat source can also be tipless and have various geometries. For example, a microcantilever hotplate can be used, as described in J. Lee & W. King, “Microcantilever hotplates: Design, fabrication, and characterization,” Sensors and Actuators A, 136 (2007) 291-298, which is incorporated herein by reference in its entirety.

### Radiation Cure Embodiment

Another embodiment comprises a radiation cure step. In this embodiment, heating can also be performed to supplement the radiation cure, such as before, during, or after the heating cure step. Heating can also occur by the natural action of radiation cure.

The ink can cure upon exposure to UV, UV-visible, or visible light, preferably at the wavelength used for lithographic exposure or photomask inspection. Sources of UV light include but are not limited to lasers, such as excimer lasers at a wavelength of 157 nm (F₂), 193 nm (ArF) and 248 nm (KrF), and UV lamps, such as mercury lamps (184.9 nm), zinc lamps (213.9 nm), excimer lamps at a wavelength of 126 nm (Ar), 146 nm (Kr), 172 nm (Xe), 193 nm (ArF), 222 nm (KrCl) and the like. Excimer lasers are commercialized by Lambda Physik (Ft. Lauderdale, Fla.) and GAM lasers (Orlando, Fla.); excimer lamps are available from Resonance (Ontario, CA), Radium Lampenwerk (Wipperfurth, Germany) and Hoya Candeo (Japan), for example.

Irradiation conditions can be varied depending on the ink and photomask. Preferably, the irradiation conditions are below the damage threshold of the photomask. For example, an ArF excimer laser can be pulsed at about 5 mJ/cm²/pulse to about 100 mJ/cm²/pulse, such as about 10 mJ/cm²/pulse to about 30 mJ/cm²/pulse, and more specifically about 13 mJ/cm²/pulse to about 20 mJ/cm²/pulse. The total dose can be determined by the pulse time, pulse intensity, and number of pulses. The number of pulses can be varied between 1 pulse to 60,000 pulses. The total dose can be about 50 mJ/cm² to about 1,000 mJ/cm², such as about 100 mJ/cm² to about 700 mJ/cm², and more specifically about 200 mJ/cm² to about 400 mJ/cm².

Tips/Cantilevers/Instruments

The tip is not particularly limited but can be a nanoscopic tip, such as for example a scanning probe microscopic tip, or specifically an atomic force microscope (AFM) tip. The tip can be located at the end of a long cantilever such as used in an AFM. The tip can be longer than is customarily used for AFM imaging, having relative high aspect ratios. The tip can be made of Si₃N₄, Si, SiOₓ, carbon like diamond (CLD), diamond, doped tips with metal and semiconductor materials, etc. Arrays of tips can be used. The tips can be used with or without supporting cantilevers. The tip can have a tip radius of, for example, 100 nm or less, or 50 nm or less, or 25 nm or less.

The tip can be coated with a polymer, such as polydimethysiloxane (PDMS)-coated stamp tip, as described in U.S. Publication Number 2005/0255237 to Zhang et al. (NanoInk), which is incorporated herein by reference in its entirety. The tip used for imaging the photomask can be different from the tip used for depositing inks. For example, imaging can be performed using a bare Si₃N₄ tip, while ink deposition is performed using a PDMS-coated stamp tip. The tip used for depositing inks may be cleaned prior to being coating with an ink. For example, the writing tip can be cleaned in RCA1 solution (H₂O₂:NH₄OH:H₂O 1:1:5 by volume) for 10 min at 70° C. A third tip may comprise a resistive heating element, such as discussed with respect to in FIGS. 1A-1B. A fourth tip may comprise a subtractive repair tip. Alternatively, the fourth tip is omitted and the imaging tip is used for subtractive repair.

The tip can be coated with a conductive material, such as a metal. For example, a Si₃N₄ AFM tip can be first coated with 3 nm of titanium (Ti) and can be then coated with an additional 10 nm of gold (Au). The metal coating can be thicker or thinner, and different metals can be used such as Cr, W, etc, or conductively-doped AFM tips can be used. These conductive tips can be used, for example, to reduce or eliminate the problem of electrostatic buildup when depositing high Mo content inks onto quartz or MoSi masks. Without wishing to be bound to any particular theory, it is believed that the electrostatic charges are dissipated or neutralized when the conductive tip is brought into contact with the charged mask. The conductive tip can be modified with hydrophobic or hydrophilic molecules, for example via thiol functionalization of a gold-coated tip.

The tip can be dipped into a reservoir containing an ink. Prior to DPN® printing, the tip can be bled by repeatedly contacting it with a sacrificial substrate, until the ink deposition rate decreases and stabilizes. The deposition rate and print characteristics can be further controlled by varying such parameters as the dwell time, scan rate, scan mode (e.g., contact, non-contact, intermittent-contact modes), and spring constant of the AFM cantilever.

Instruments and accessories for microscale and nanoscale lithography can be obtained from NanoInk (Chicago, Ill.), including the NSCRIPTOR™ instrumentation.

Photomask

A variety of photomasks can be used including those used for recognized nodes such as the 65 nm node, the 45 nm node, and the like. Mask defects are known in the art and include, for example, clear defects, which may be repaired by an additive repair process, and opaque defects, which may be repaired by a subtractive repair process. Clear defects, which are missing or incomplete features, include, for example: pin-holes, broken or thinned lines, edge or notch defects, and corner defects. The defect region can be microscale or nanoscale.

Exemplary types of masks include the alternating aperture phase shifting photomasks (AAPSMs) and embedded attenuated phase shifting photomasks (EAPSMs). AAPSMs, also called strong-shifters, can be fabricated by etching 180°-phase-shifting windows in alternating clear areas of a quartz mask. EAPSMs, also called weak-shifters, can be fabricated by depositing a partially-transmitting 180°-phase-shifting material, such as molybdenum silicide (MoSi), near clear openings of the photomask. Phase shift masks and methods of forming them are described in U.S. Pat. No. 7,011,910 to Shiota et al., which is incorporated herein by reference in its entirety.

The photomasks may be cleaned prior to being repaired. For example, the photomask can be cleaned with piranha solution (a mixture of sulfuric acid and hydrogen peroxide known in the art) for 60 seconds followed by 5.5 minutes in RCA1 solution (H₂O₂:NH₄OH:H₂O 1:1:5 by volume) at 120° C. and by a deionized water (DI) rinse.

Ink Composition

The ink composition can be adapted for the cure, including for the heating cure embodiment or the radiation cure embodiment. The ink composition can be further adapted to provide suitable optical properties including sufficient transparency and sufficient refractive index to approximately match that of the photomask. Matching of the cured ink with the photomask can be achieved at or around the wavelengths used for lithographic exposure, such that the performance of the repaired photomask is not substantially worse than that of a photomask having no defect. Color matching can be used as a facile indicator for larger-scale repair areas under optical microscopy inspection.

The ink composition can comprise a carrier solvent and a sol-gel precursor compound. Examples of carrier solvents include organic liquids including alcohols and alkanes. The alcohol may have the formula CₙH₍₂ₙ₊₂₎O, wherein 4≦n≦17 Protic or aprotic solvents can be used. Examples include acetone, decanol, dimethylformamide (DMF), and alpha terpinyl. The viscosity and evaporation rate of the ink composition can be adjusted by varying the ratio of solvent to sol-gel precursor. For example, the ink composition may contain solvent, relative to the precursors in the ink, at about 5 wt % to about 30 wt %, such as about 10 wt % to 25 wt %. In addition, the viscosity of the ink composition can be adjusted by varying the amount and size of the solvent molecule, such as by varying the length of a long carbon chain alcohol (e.g., CH₃(CH₂)ₙOH where n is greater than 5). Other solvents include diglyme [bis(2-methoxyethyl)] and poly(ethylene glycol) [“PEG”]. For example, if PEG is used, its molecular weight may be about 200 g to about 600 g, such as about 250 g. If DMF is present in the ink together with PEG, then a volumetric ratio of DMF to PEG can be about 1:10 to about 10:1, such as about 1:5 to about 5:1. Where MoSi precursors are dissolved in decanol, the volumetric ratio of the MoSi precursors and decanol solution to DMF/PEG can be about 1:10 to about 10:1, such as about 1:5 to about 5:1. Alternatively, acetone is substituted for DMF/PEG. For example, the volumetric ratio of the MoSi precursors and decanol solution to acetone is about 1:10 to about 10:1, such as about 1:5 to about 5:1.

The ink composition can contain at least one silicon dioxide precursor that is adapted to provide a silicon dioxide material upon cure. For example, the ink composition can include at least one photocurable silsesquioxane, such as poly(2-chloroethyl)silsesquioxane (“PCESQ”), which has an irradiation wavelength of 193 nm and results in a micro- or nanostructure primarily comprising silica. Other silicon dioxide precursors include but are not limited to: polyhedral oligomeric silsesquioxanes (POSS®) commercialized by Hybrid Plastics, silicon alkoxide, and tetraethoxyorthosilicate. The silsesquioxanes disclosed in U.S. Pat. No. 5,853,808, which is incorporated herein by reference in its entirety, can also be used.

PCESQ is suitable as a medium-temperature thermocurable ink, especially when mixed with a fluoride ion catalyst. Catalysis with a fluoride ion catalyst (e.g., tetrabutylammonium fluoride) lowers the silsesquioxane curing temperature, such as below 250° C., preferably below 200° C.

The ink composition can also contain a metal precursor that is adapted to provide a metal material upon cure, such as metal nanoparticles, metal salts, metal alkoxides, and metal acetylacetonates. Molybdenum nanoparticles includes molybdenum silicide and molybdenum oxide nanoparticles or powders. Preferably, the average diameter of the nanoparticles is far smaller than the typical defect to be repaired, for example, a few nanometers in diameter. The metal precursors also include molybdenum salt or molybdenum acid salt. Examples include molybdosilicic acid and salts thereof, molybdenum trioxide, heteropolyacids of molybdenum, ammonium molybdate, and alkali metal or alkaline earth metal salts of the molybdate anion. For example, MoClₓ or MoO_{y}Clₓ is formed by adding MoO₂ nanoparticles in a solution consisting of 1:1 ratio by volume of HCl and H₂O₂. Other molybdenum compounds include: molybdenum(III) chloride (MoCl₃), molybdenum(V) chloride (MoCl₅), molybdenum(VI) dichloride dioxide (MoO₂O₂), molybdenum(VI) tetrachloride oxide (MoOCl₄).

Metal alkoxides include alkoxides of the following metals: Sc, Ga, Y, La, Ln, Si, Ti, Ge, Zr, Hf, Nb, Ta, Mo, W, Fe, Co, Ni, Re, Pd. Examples of metal alkoxides include: Ti(OC₃H₇-iso)₄, Nb₂(OCH₃)₁₀, Ta₂(OCH₃)₁₀, [MoO(OCH₃)₄]₂, Re₂O₃(OCH₃)₆, Re₄O₆(OCH₃)₁₂, and Re₄O₆(OC₃H₇-iso)₁₀. For example, molybdenum(V) ethoxide is used. The synthesis and isolation of molybdenum(V) alkoxides and bimetallic alkoxides are described in “The solution thermolysis approach to molybdenum(V) alkoxides: synthesis, solid state and solution structures of the bimetallic alkoxides of molybdenum(V) and niobium(V), tantalum(V) and tungsten(VI),” A. Johansson et al., J. Chem. Soc., Dalton Trans. 2000, 387-398, which is incorporated herein by reference in its entirety.

Metal acetylacetonates include acetylacetonates of the following metals: Ti, Fe, Ga, Zn, In, V, Nb, Ta, Hf, Mo, Mn, Cr, and Sn, as described in “Metal Acetylacetonates as General Precursors for the Synthesis of Early Transition Metal Oxide Nanomaterials,” A. Willis et al., J. Nanomaterials 2007, 1-7 (Article ID 14858), which is incorporated herein by reference in its entirety. For example, molybdenum(VI) oxide Bis(2,4-pentanedionate) is used.

The optical properties of the ink can be tuned by varying the concentration of ink components, such as by varying the ratio of metal precursor to silicon dioxide precursor within the ink. For example, the atomic ratio of Mo to Si in the ink can be equal to about 1:50 to about 50:1, such as about 1:25 to about 25:1, for example about 1:10 to about 10:1, and more specifically about 1:5 to about 5:1. Control of the atomic ratio of Mo to Si can be performed by varying either the volumetric or weight ratios of molybdenum precursors to silicon dioxide precursors. For example, the volumetric ratio of the molybdenum precursor to the silicon dioxide precursor is in the range of about 1:50 to about 50:1, such as about 1:25 to about 25:1, for example about 1:10 to about 10:1, and more specifically about 1:5 to about 5:1. In an alternative embodiment, the weight ratio of the molybdenum precursor to the silicon dioxide precursor is in the range of about 1:50 to about 50:1, such as about 1:25 to about 25:1, for example about 1:10 to about 10:1, and more specifically about 1:5 to about 5:1. For example, a sol-gel ink formulation includes PCESQ and a molybdenum precursor made from at least one of Mo(V) ethoxide or molybdenum(VI) oxide Bis(2,4-pentanedionate).

The ink composition can be adapted to have the ability to coat a tip, and then be deposited from the tip to a substrate.

Properties of Repaired Mask

An advantage of the repaired mask is that the cured ink adheres well to the mask and survives washing steps commonly used in the semiconductor industry. For example, the cured ink can survive repeated washing steps in piranha solution, RCA1 solution, RCA2 solution, and deionized water. Preferably, the thermal expansion coefficient of the cured ink is approximately equal to that of the photomask, thereby allowing the cured ink to expand and contract with the surrounding photomask during thermal cycling without cracking or pealing off from the photomask.

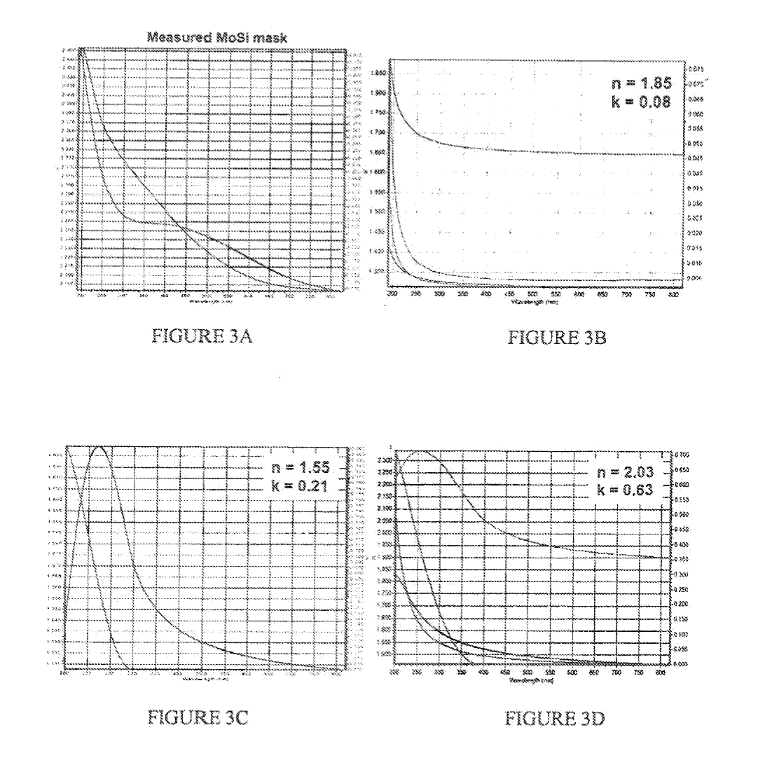

A further advantage of the repaired mask is that the optical properties of the cured ink approximately match those of an undamaged mask. For example, the optical properties of Mo—Si based EAPSM films are set forth in H. Kobayashi et al., “Photomask blanks quality and functionality improvement challenges for the 130-nm node and beyond,” Proc. SPIE, Vol. 4349, p. 164-169, 17th European Conference on Mask Technology for Integrated Circuits and Microcomponents, Uwe F. Behringer; Ed. (2001), particularly FIG. 3, which is incorporated herein by reference in its entirety. Transmittance of the cured ink can be, for example, about 5% to about 25% of incident light. It can be, for example, 5% to 10%, or 10% to 20% for high transmittance masks. The transmittance of the cured ink is tuned by varying, for example, the refractive index (n), the extinction coefficient (k), and the thickness (t) of the cured ink. For incident light with a wavelength of 193 nm, the refractive index (n) of the cured ink can equal about 1.00 to about 2.6, such as about 1.30 to about 2.45, for example about 2.0 to about 2.4, and more specifically about 1.55 to about 2.03. For incident light with a wavelength of 193 nm, the extinction coefficient (k) of the cured ink can equal about 0.03 to about 0.90, such as about 0.20 to about 0.75, for example about 0.3 to about 0.6, and more specifically about 0.38 to about 0.63. The thickness (t) of the cured ink can vary from a few nanometers to several hundred microns or more, but is preferably about 10 nm to 1,000 nm, such as about 30 nm to about 650 nm, and more specifically about 50 nm to about 100 nm.

The invention is further described with use of the following non-limiting examples, which include a description of the figures.

### Example 1

### Preparation, DPN® Printing and Thermal Curing of PCESQ Compositions

A commercially-available alternating-aperture photomask (AAPSM) was cleaned with piranha solution (a mixture of sulfuric acid and hydrogen peroxide known in the art) for 60 s followed by 5.5 min in RCA1 solution (H₂O₂:NH₄OH:H₂O 1:1:5 by volume) at 120° C. and by a deionized water (DI) rinse. A commercially-available silicon nitride tip was cleaned in RCA1 for 10 min at 70° C. A sol-gel mixture was prepared by mixing poly(2-chloroethyl)silsesquioxane (“PCESQ”) and decanol (density 0.8297 g/ml) in a 10:1 ratio by volume. The tip was coated by being immersed in the sol-gel mixture for 15 s.

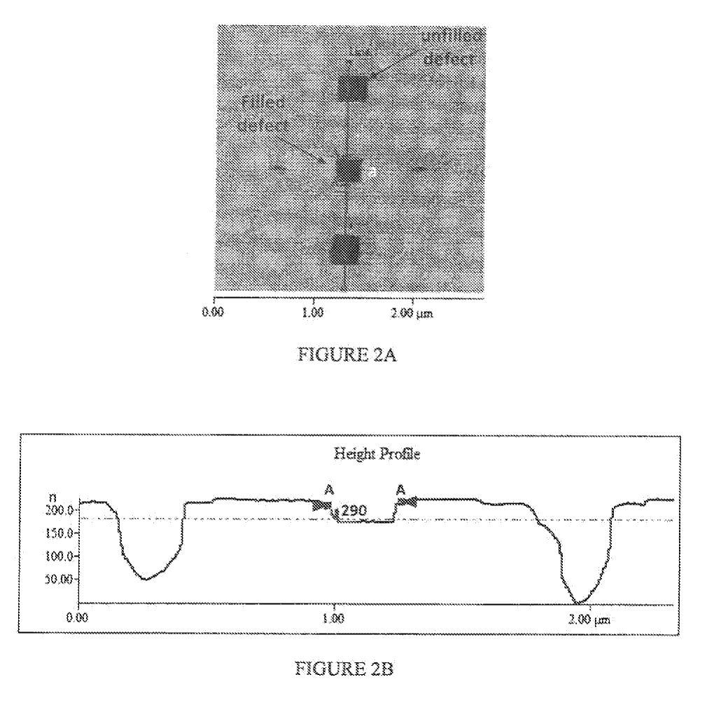

A portion of the mask was imaged by AFM, and a region comprising three apertures at least 200-nm in depth was located. FIG. 2A shows an AFM image of the AAPSM after the middle aperture was repaired via DPN® printing by using a scanning probe microscopy instrument NSCRIPTOR™ (NanoInk, Skokie Ill.) under ambient conditions (22° C. to 24° C. and 20% to 40% relative humidity). After deposition, the substrate was heated for 16 hr in an oven at 120° C. followed by 5 min of heating with a hand-held heat gun (˜300° C.). FIG. 2B shows a height profile line-scan along “Line 1” in FIG. 2A showing that the middle aperture was substantially filled.

The dwell time of the tip over the defective region can be varied. Optionally, subtractive repair can be performed to remove excess cured material.

Cured SiO₂ structures formed by the above-described method exhibited remarkable robustness to cleaning with piranha solution, RCA1 solution, and rinsing with DI water on quartz, glass, and silicon oxide. For example, the change in average height and width of the microdots after repeated cleaning was less than about 3% (within the margin of error). Thus, the cured SiO₂ structures are chemically and mechanically stable.

### Example 2

### Photocuring of PCESQ Compositions

An array of 33 microdots was formed by depositing poly(2-chloroethyl)silsesquioxane (“PCESQ”) on a quartz substrate using DPN® printing as described in Example 1. Prior to photocuring, the uncured sol-gel structures were too soft to be imaged by AFM but could be easily observed via optical microscopy. These structures were then heated using deep UV radiation with a commercial ArF excimer having a 193 nm wavelength. Irradiation was performed using a pulse does of 13.3 mJ/cm²/pulse and a total dose of 250 J/cm².

### Example 3

### Optical Properties of MoSi Compositions

A 66 nm-thick thin film of MoSi was deposited by physical vapor deposition (PVD). Ellipsometry measurements were performed on the MoSi film to determine the film's refractive index (n) and extinction coefficient (k) as a function of wavelength. FIG. 3A is a plot of n and k versus wavelength for the PVD-deposited film. For a wavelength of 193 nm, n=2.45 and 0.38≦k≦0.55.

### Formulation:

Four different ink formulations were made (labeled A, B, C, D), and their optical properties were tested in three rounds of testing. In Round 1, formulation A(1, 2) contained 0.002 g of MoO₂ nanoparticles and 1 μL of PSESQ. Formulation B(3) contained a 1:4 volumetric ratio of MoOₓCl_{y} to PSESQ. Formulation C(4,5) contained 1:7 and 1:15 volumetric ratios of molybdenum(VI) oxide Bis(2,4-pentanedionate) to PCESQ, respectively. Formulation D(6,7) contained 1:200 and 1:400 volumetric ratios of Mo(OCH₂CH₃)₅ to PCESQ, respectively. Table 1 shows the ellipsometry data for Round I at a wavelength of 193 nm.

TABLE 1
Round I

| Ink formulation | n | k |
|---|---|---|
| A(1) | 1.35 | 0.07 |
| A(2) | 1.15 | 0.12 |
| B(3) | 1.00 | 0.07 |
| C(4) | 1.60 | 0.05 |
| C(5) | 1.85 | 0.08 |
| D(6) | 1.35 | N/A |
| D(7) | 1.42 | 0.03 |

In Round II, formulation D(1, 2, 3, 4) contained Mo(OCH₂CH₃)₅ and PCESQ in the following volumetric ratios: 1:30, 1:60, 1:90, and 1:120, respectively. Formulation C(5, 6, 7) contained molybdenum(VI) oxide Bis(2,4-pentanedionate) and PCESQ in the following volumetric ratios: 1:4, 1:8, and 1:12, respectively. Table 2 shows the ellipsometry data for Round II at a wavelength of 193 nm.

TABLE 2
Round II

| Ink formulation | n | k |
|---|---|---|
| D(1) | 1.46 | 0.018 |
| D(2) | 1.03 | 0.032 |
| D(3) | 1.19 | 0.035 |
| D(4) | 1.00 | 0.040 |
| C(5) | 1.55 | 0.195 |
| C(6) | 1.55 | 0.155 |
| C(7) | 1.50 | 0.046 |

In Round III, formulation C(1, 2, 3, 4) contained molybdenum(VI) oxide Bis(2,4-pentanedionate) and PCESQ in the following volumetric ratios: 1:1, 5:1, 10:1, and 20:1, respectively. Formulation D(5, 6, 7) contained Mo(OCH₂CH₃)₅ and PCESQ in the following volumetric ratios: 2.5:1, 1:1+decanol, and 1.5:1 respectively. Table 3 contains the ellipsometry data for Round III at a wavelength of 193 nm.

TABLE 3
Round III

| Ink formulation | n | k |
|---|---|---|
| C(1) | 1.30 | 0.19 |
| C(2) | 1.15 | 0.22 |
| C(3) | 1.65 | 0.89 |
| C(4) | 1.65 | 0.75 |
| D(5) | 1.29 | 0.35 |
| D(6) | 1.34 | 0.23 |
| D(7) | 2.03 | 0.63 |

FIGS. 3B-3D are plots of measured n and k versus wavelength for selected inks from Rounds I, II, and III, respectively. Specifically, FIG. 3B is a plot of n and k versus wavelength for Round I, Formulation C(5). FIG. 3C is a plot of n and k versus wavelength for Round II, Formulation C(5). FIG. 3D is a plot of n and k versus wavelength for Round III, Formulation D(7). Notably, the n and k curves in FIGS. 3C-3D follow the same general trends as the CVD-deposited MoSi film in FIG. 3A. Final values for n and k are shown for 193 nm wavelengths.

### Example 4

### Preparation of Mo(V) Ethoxide and PCESQ Compositions

Eight ink formulations were prepared by adding decanol (density 0.8297 g/ml) to an ethanolic stock solution of Mo(V) ethoxide and leaving the solution open in an ependorf tube for 24 to 72 hours until the ethanol evaporated. After evaporation, poly(2-chloroethyl)silsesquioxane (“PCESQ”) was added to solution. The relative quantities of each component are shown in Table 4 for each ink formulation. The weight percent of decanol in each ink formulation was measured relative to the total weight of Mo(V) ethoxide and PCESQ.

TABLE 4

| | Mo(V) ethoxide | PCESQ | Decanol |
|---|---|---|---|
| Ink | (mg) | (mg) | (wt. %) |
| 1 | 15 | 60 | 19 |
| 2 | 8 | 24 | 13 |
| 3 | 8 | 24 | 18 |
| 4 | 9.8 | 19.4 | 16 |
| 5 | 12.3 | 13.5 | 17 |
| 6 | 30.2 | 17.3 | 26 |
| 7 | 28.5 | 14.4 | 22 |
| 8 | 15.4 | 62.2 | 22 |

### Example 5

### Preparation of MoSi Thin Films from Mo(V) Ethoxide and PCESQ Compositions

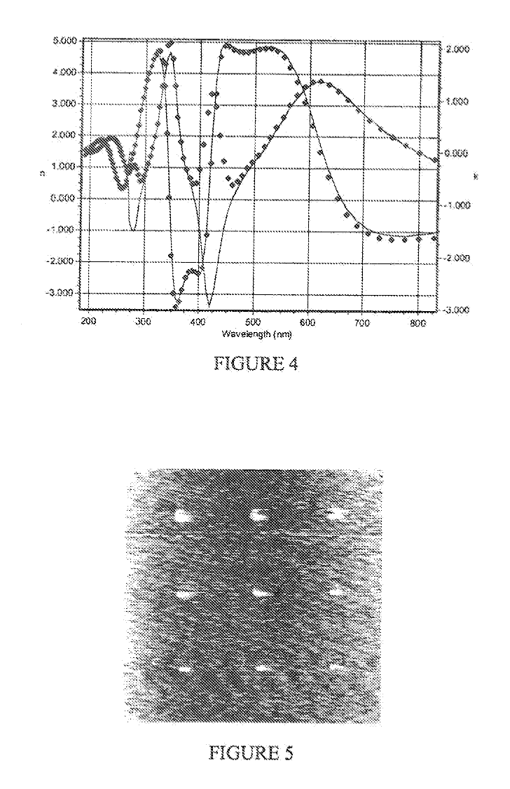

An ink formulation was prepared by adding decanol (density 0.8297 g/ml) to an ethanolic stock solution of Mo(V) ethoxide and leaving the mixture open in an ependorf tube for 24 to 72 hours until the ethanol evaporated. After evaporation, poly(2-chloroethyl)silsesquioxane (“PCESQ”) was added to the solution. The ratio of Mo(V) ethoxide to PCESQ was 1:10 by weight. The amount of decanol was 20 wt. % of the total weight of Mo(V) ethoxide and PCESQ. A silicon dioxide substrate (1 inch square) was treated with HF prior to being spin coated with 400 μL of the ink formulation for 5 s at 500 rpm, followed by 30 s at 1500 rpm. The film was heated for 60 min at about 300° C. The result was a thin film of MoSi having a thickness of 240 nm. Thicknesses of about 100 nm can be obtained, for example, by depositing less than 400 μL, of ink, such as about 50 μL to about 300 μL. Ellipsometry measurements were performed on the cured ink, and curve fitting was performed to obtain the film thickness and n and k values. FIG. 4 shows that for a spectrum range of 1.5 eV to 6.5 eV and a film thickness of 240 nm, the values for n and k at 190 nm wavelength were 1.7 and 0.2, respectively.

### Example 6

### DPN® Printing of Mo(V) Ethoxide and PCESQ Compositions

An ink formulation was prepared by adding decanol (density 0.8297 g/ml) to an ethanolic stock solution of Mo(V) ethoxide and leaving the solution open in an ependorf tube for 24 to 72 hours until the ethanol evaporated. After evaporation, poly(2-chloroethyl)silsesquioxane (“PCESQ”) was added to solution. The ratio of Mo(V) ethoxide to PCESQ was 1:5 by volume. The amount of decanol was 20 wt. % of the total weight of Mo(V) ethoxide and PCESQ. The ink formulation was deposited from an AFM tip on a SiO₂ substrate using DPN® printing and was thermally cured at 200° C. for 1 hr. FIG. 5 shows an AFM image of a 3×3 array of cured ink microdots formed by holding the tip over each deposited region for 20 s (bottom row), 40 s (middle row), and 60 s (top row).

### Example 7

### Mo(V) Ethoxide and PCESQ Compositions with Tetrabutylammonium Fluoride Catalyst

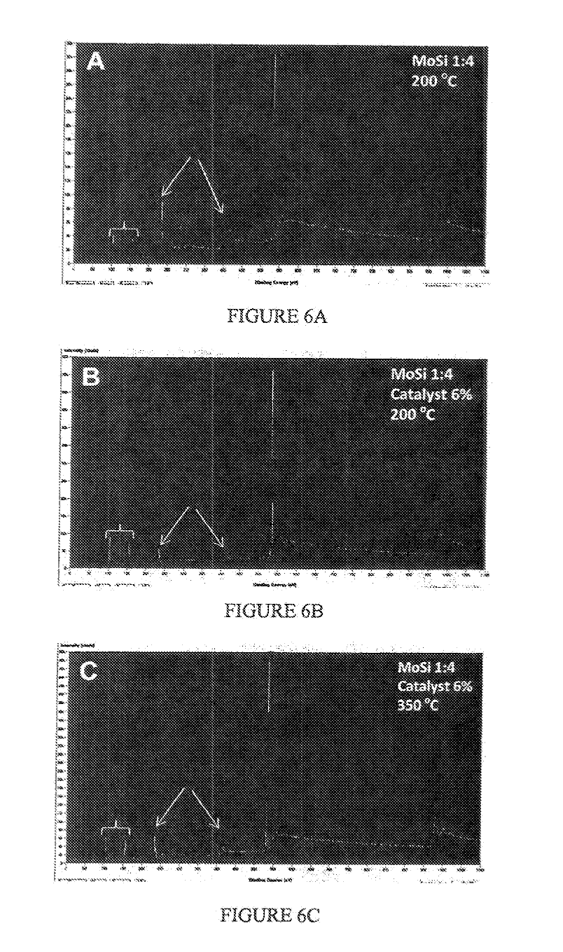

A first ink formulation was prepared by adding decanol (density 0.8297 g/ml) to an ethanolic stock solution of Mo(V) ethoxide and leaving the solution open in an ependorf tube for 24 to 72 hours until the ethanol evaporated. After evaporation, poly(2-chloroethyl)silsesquioxane (“PCESQ”) was added to solution. The ratio of Mo(V) ethoxide to PCESQ was 1:4 by weight. The amount of decanol was 20 wt. % of the total weight of Mo(V) ethoxide and PCESQ. The first ink formulation was deposited by spin coating onto a HF-treated silicon substrate. The film was heated at 200° C. for 1 hr. X-ray photoelectron spectroscopy (XPS) was performed on the film. FIG. 6A is an XPS spectrum of the cured first ink and shows the presence of a carbon peak at around 290 eV.

A second ink formulation was prepared according to the method and compositions used in the first ink formulation, except that 6 wt % tetrabutylammonium fluoride catalyst was added to the final mixture. The amount of catalyst added was 6% of the total weight of the MoSi solution. The second ink formulation was deposited by spin coating onto a HF-treated silicon substrate. The film was heated at 200° C. for 1 hr. X-ray photoelectron spectroscopy (XPS) was performed on the film. FIG. 6B is an XPS spectrum of the cured second ink and shows a much smaller peak at around 290 eV as compared with FIG. 6A, indicating a suppression of the carbon peak due to the presence of the catalyst. FIG. 6C shows an XPS spectrum of the second ink heated at 350° C. A small carbon peak is visible and is attributed to carbon contamination during sample handling. These results show that the tetrabutylammonium fluoride catalyst decreased the curing temperature of the ink formulation, as evidenced by the relatively smaller carbon peak in FIG. 6B.

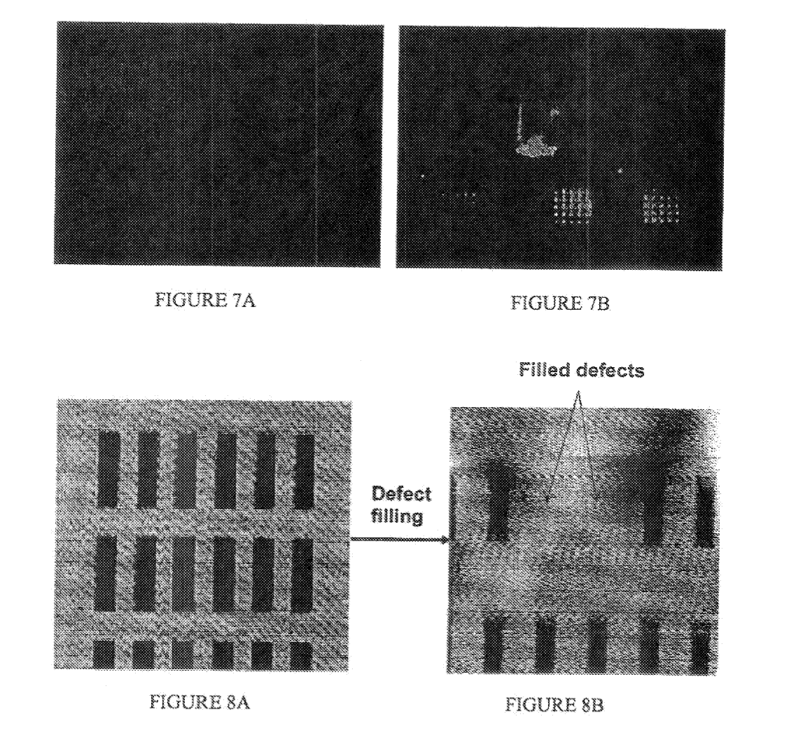

A third ink formulation was prepared by adding decanol (density 0.8297 g/ml) to an ethanolic stock solution of Mo(V) ethoxide and leaving the solution open in an ependorf tube for 24 to 72 hours until the ethanol evaporated. After evaporation, poly(2-chloroethyl)silsesquioxane (“PCESQ”) was added to solution. The ratio of Mo(V) ethoxide to PCESQ was 1:4 by weight. The amount of decanol was 20 wt. % of the total weight of Mo(V) ethoxide and PCESQ. The ratio of Mo(V) ethoxide to PCESQ was 1:4 by volume. The amount of decanol was 17 μL (20 wt. % of the total weight of Mo(V) ethoxide and PCESQ). Then, 3 wt % tetrabutylammonium fluoride catalyst was added to the third ink formulation. The amount of catalyst added was 3% of the total weight of the Mo(V)Si solution. FIGS. 7A-7B show optical microscope images of an array of defects in a photomask before (FIG. 7A) and after (FIG. 7B) the third ink formulation was deposited onto a SiO₂ surface using DPN® printing. The ink in FIG. 7B was not cured. The tip holding time was 10 s per defect.

### Example 8

### Preparation of Mo(VI) Oxide Bis(2,4-pentanedionate) and PCESQ Compositions

Mo(VI) oxide Bis(2,4-pentanedionate) was dissolved in 500 μL of ethanol and reduced for several weeks at room temperature. Reduction was observed to begin after one week and reached completion after four weeks. The color of the solution changed from a yellow color to dark blue upon reduction. The solution was then added together with poly(2-chloroethyl)silsesquioxane (“PCESQ”) to decanol (density 0.8297 g/ml). The relative quantities of each component are shown in Table 5 for each ink formulation. In order to determine the weight amount of Mo(VI), the solvent of a known amount (20 μL) of the ethanolic Mo(VI) solution was evaporated. The determined weight was used as the standard weight for a 20 μL Mo(VI) sample. Appropriate amounts of PCESQ were added depending on the desired ratio, for example the 20 μL solution yielded a 0.001 g solid after ethanol evaporation. Thus, to obtain a 0.01 g of Mo(VI), 200 μL of solution was used. The weight percent of decanol in each ink formulation was measured relative to the total weight of Mo(VI) oxide Bis(2,4-pentanedionate) and PCESQ.

TABLE 5

| | Mo(VI) oxide Bis(2,4- | |
|---|---|---|
| | pentanedionate):PCESQ | Decanol |
| Ink | (Volumetric ratio) | (wt. % of total) |
| 1 | 1:64 | 20 |
| 2 | 1:20 | 20 |
| 3 | 1:10 | 20 |
| 4 | 1:4 | 20 |
| 5 | 1:1 | 20 |
| 6 | 2:1 | 20 |
| 7 | 4:1 | 20 |

FIGS. 8A-8B show AFM images of an array of defects before (FIG. 8A) and after (FIG. 8B) defect filling was performed with Ink Formulation 3 (1:10 Mo(VI) oxide Bis(2,4-pentanedionate):PCESQ by volume) using DPN® printing by slowly scanning the coated AFM tip across the defect area. The samples were cured at 200° C. for 1 hr. Each defect feature has a length and width of about 2 μm and 0.6 μm, respectively.

### Example 9

### DPN® Printing of Mo(V) Ethoxide and PCESQ Compositions

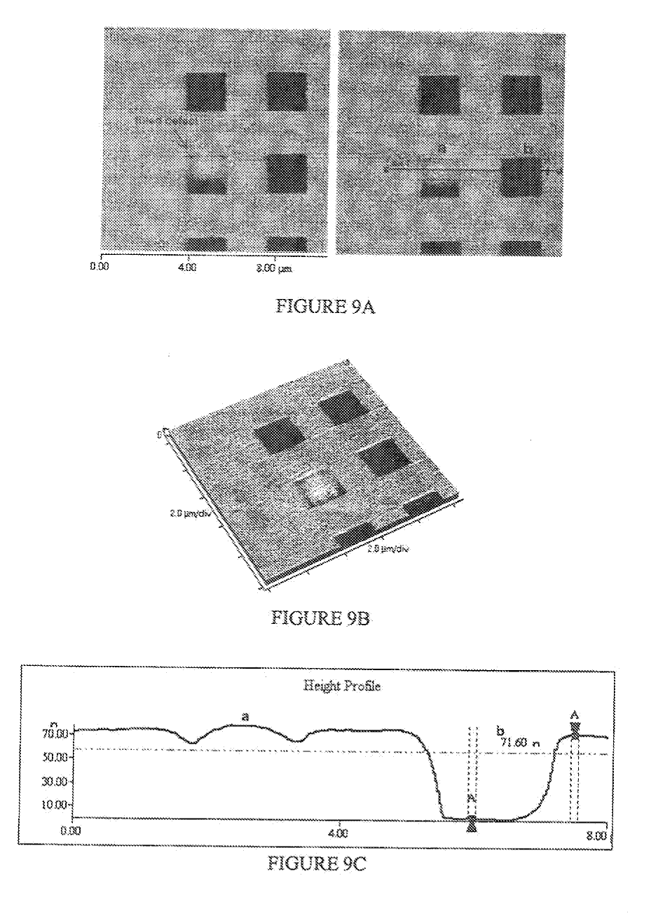

An ink formulation was prepared according to the method described in Example 5. The ratio of Mo(V) ethoxide to PCESQ was 1:10 by weight. The amount of decanol was 20 wt. % of the total weight of Mo(V) ethoxide and PCESQ. Then, a 4:1 ratio by volume of DMF and PEG (molecular weight 250 g) was added to the first ink formulation. The ratio of the Mo(V)Si and the DMF:PEG solutions was 1:5. The ink formulation was deposited from an AFM tip into a 2 μm-wide, 70 nm-deep aperture of a quartz photomask using DPN® printing. The deposited ink was cured at 200° C. for 1 hr. FIGS. 9A-9B show two- and three-dimensional AFM images, respectively, of the aperture that is substantially filled with the cured ink. FIG. 9C shows a height profile line-scan along “Line 1” in FIG. 9B, with locations “a” and “b” representing the repaired aperture and an adjacent unfilled aperture, respectively.

### Example 10

### Stability of Cured MoSi Inks

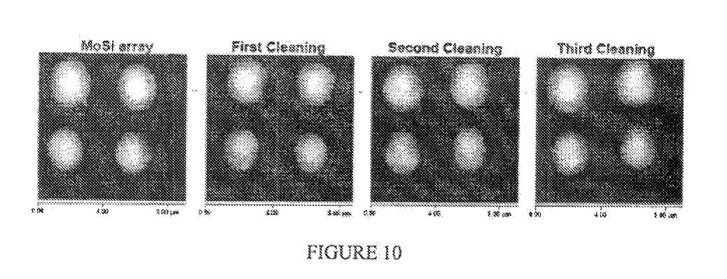

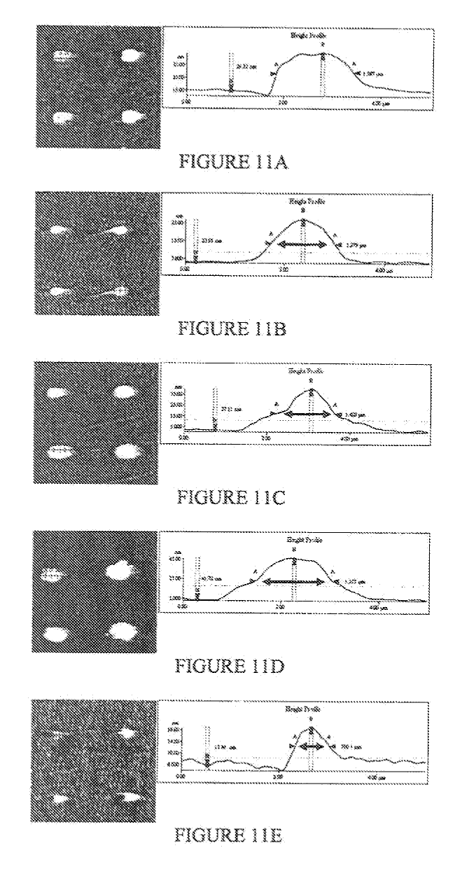

An array of MoSi microdots was formed by depositing an ink formulation containing Mo(V)Si 1:10 ratio in 20 wt % decanal on a SiO₂ substrate using DPN® printing and heating the array in an oven at 225° C. for 60 min. After curing, the array was subjected to three rounds of cleaning under the following conditions: 120 s in piranha (3:1 by volume H₂SO₄:H₂O₂) at 65° C., followed by sonication for 30 s at 20 watt/cm², followed by sonication for 30 s at 4 watt/cm², followed by 120 s DI rinse, followed by heating for 15 min at 100° C. FIG. 10 shows a series of AFM images of the array before and after each round of cleaning. The average height (83 nm) and width (1.7 μm) of the MoSi microdots before and after the three rounds was within 3% (within the margin of error) and thus was not appreciably affected by the aggressive cleaning regimen. Similar results (not shown) were obtained for MoSi microdots having an average height and width of 14.5 nm and 600 nm, respectively.

### Example 11

### Photocuring of Mo(V) Ethoxide and PCESQ Compositions

An array of MoSi microdots was formed by depositing an ink formulation containing Mo(V) ethoxide and PCESQ on SiO₂ and quartz mask substrates using DPN® printing and photocuring by excimer laser irradiation. The wavelength of the excimer laser was 193 nm under various irradiation conditions: Energy density was varied from 5, 25, 50, 75 and 100 mJ/cm². Repetition rate was varied from 20 and 50 Hz. Number of pulses was varied from 100, 4000, 6000, 7600, 12000 and 60000. Process time was varied from 5, 80, 120, 200, 240, 300, 390 and 1200 sec.

FIGS. 11A-11E show AFM images and corresponding line scans of the resultant 2×2 MoSi microdot arrays. In FIG. 11A, the irradiation conditions were: 5 mJ/cm², 50 Hz, 60000 pulses, 1200 s, 10 sec. In FIG. 11B, the irradiation conditions were: 25 mJ/cm², 50 Hz, 12000 pulses, 240 s, 10 sec. In FIG. 11C, the irradiation conditions were: 50 mJ/cm², 20 Hz, 6000 pulses, 300 s, 10 sec. In FIG. 11D, the irradiation conditions were: 75 mJ/cm², 20 Hz, 4000 pulses, 200 s, 10 sec. In FIG. 11E, the irradiation conditions were: 25 mJ/cm², 50 Hz, 12000 pulses, 240 s, 1 sec.

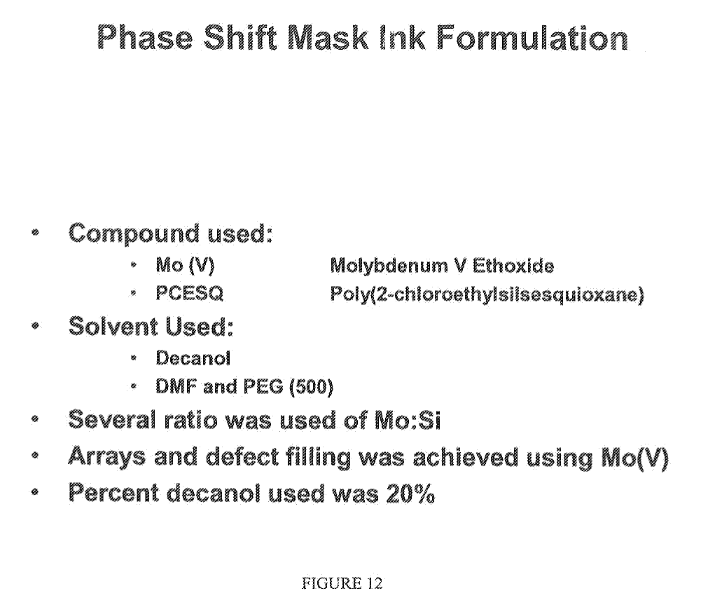

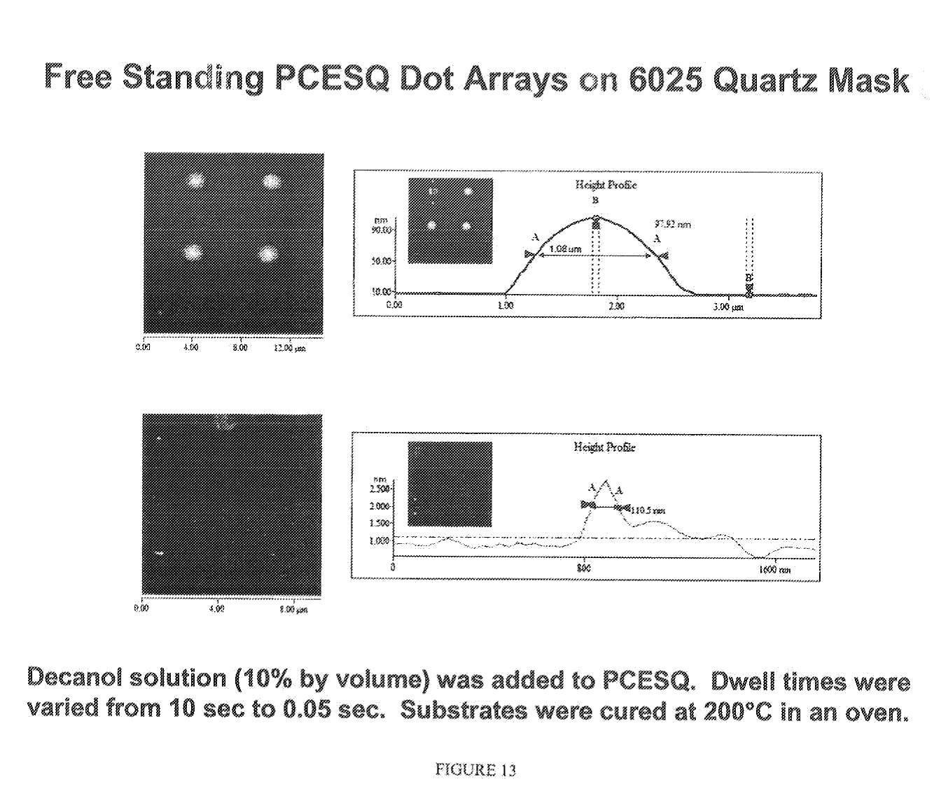

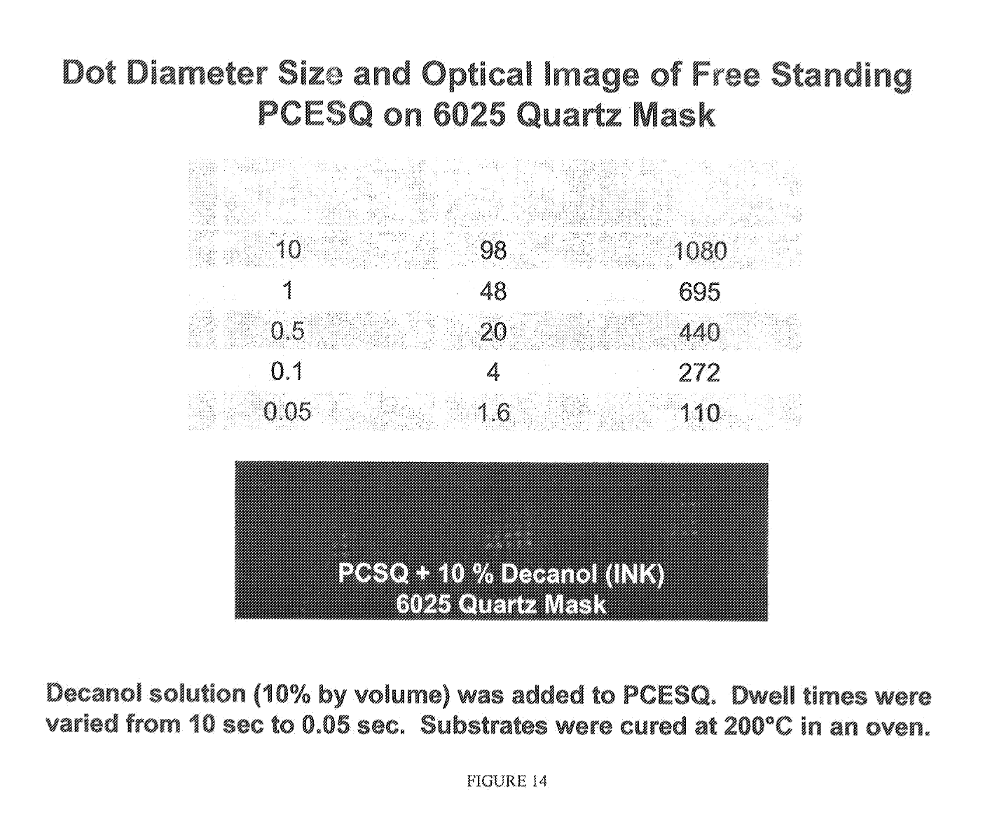

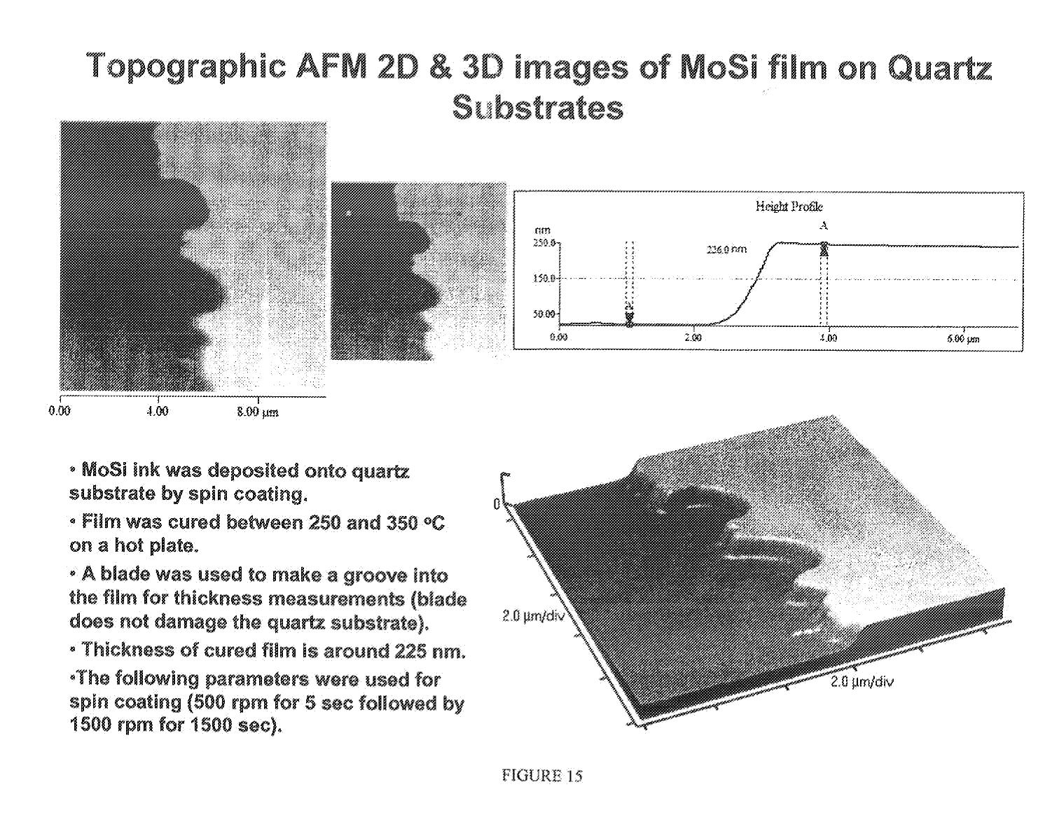

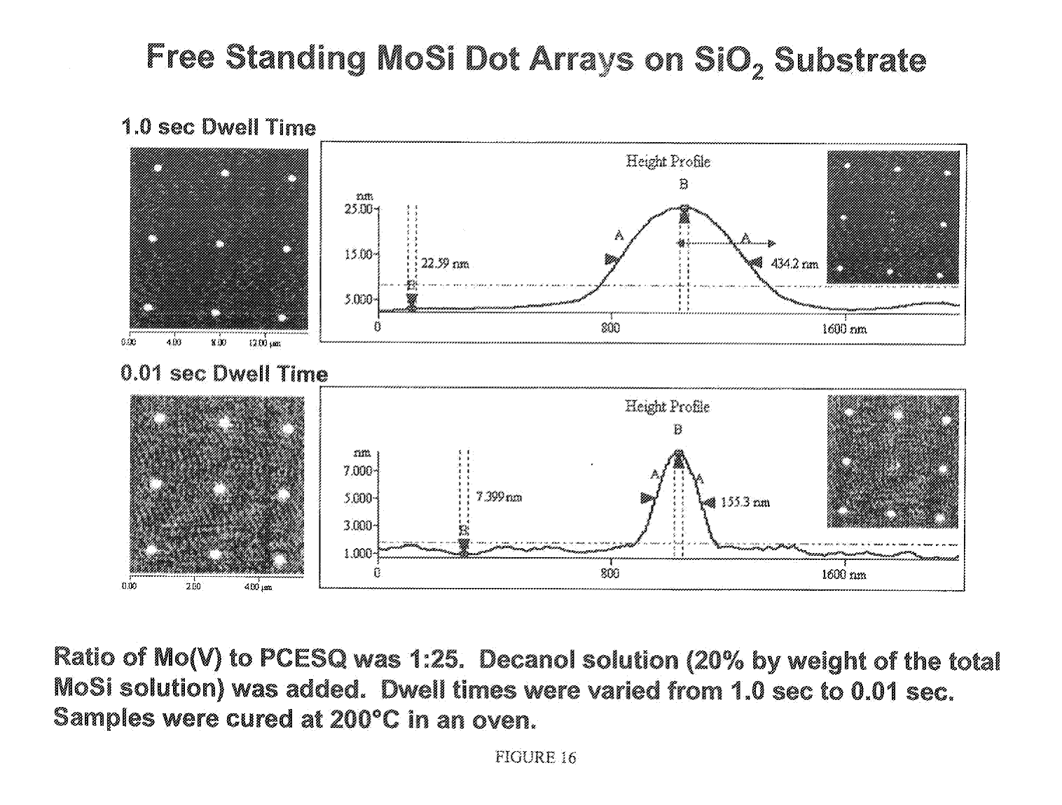

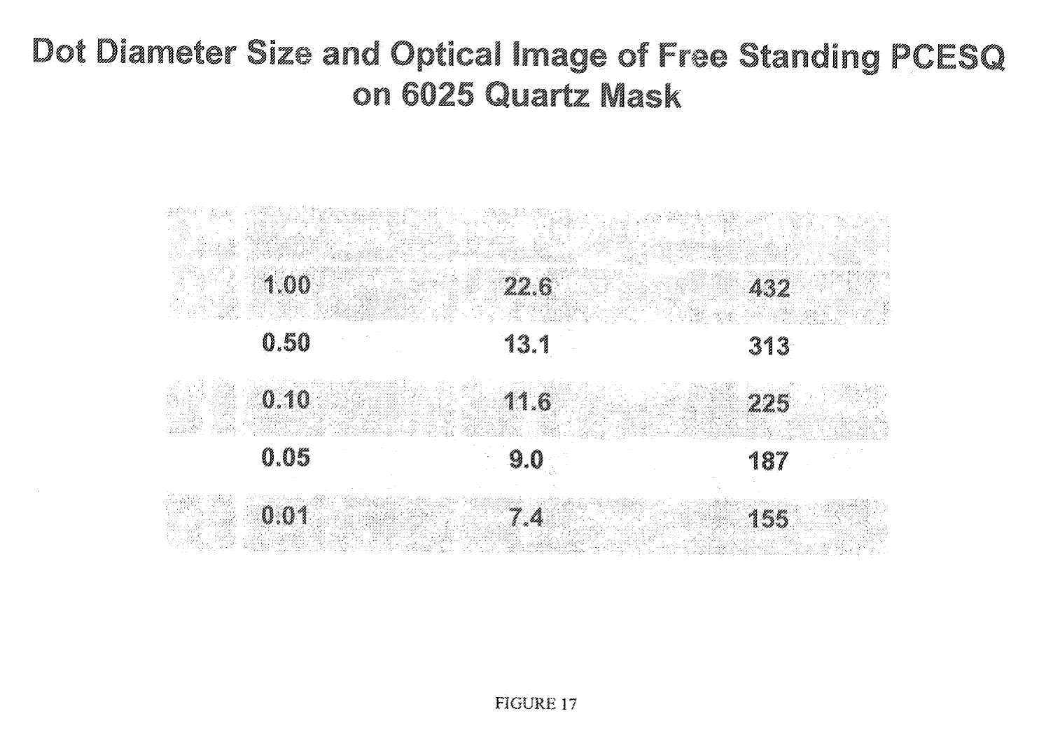

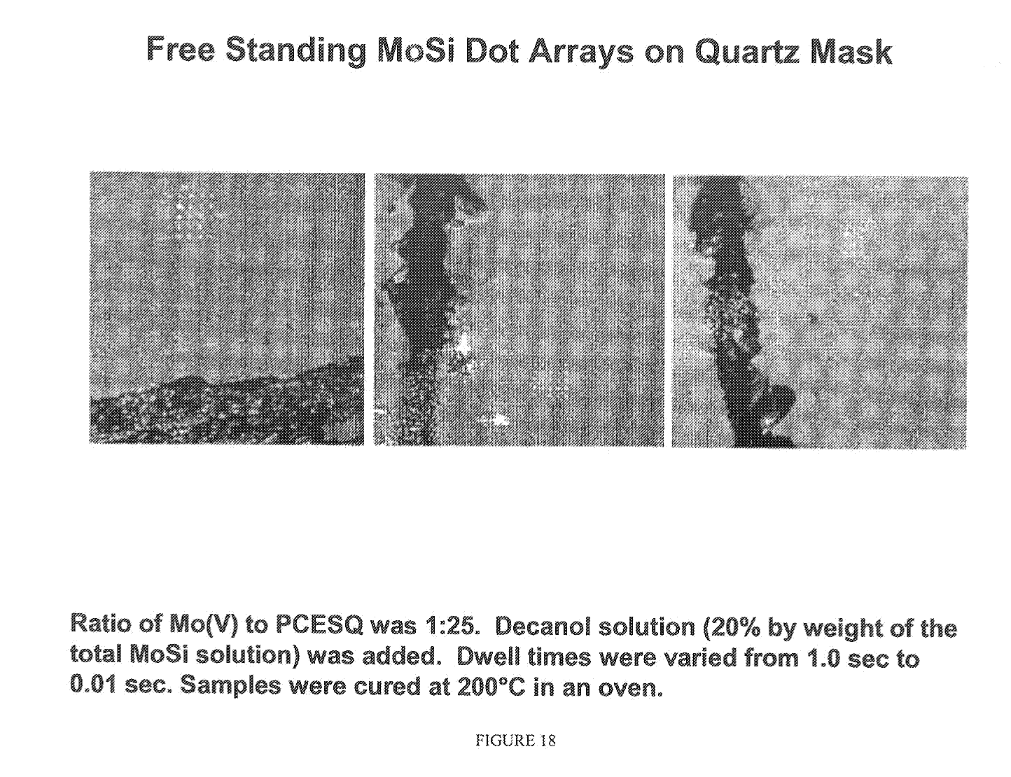

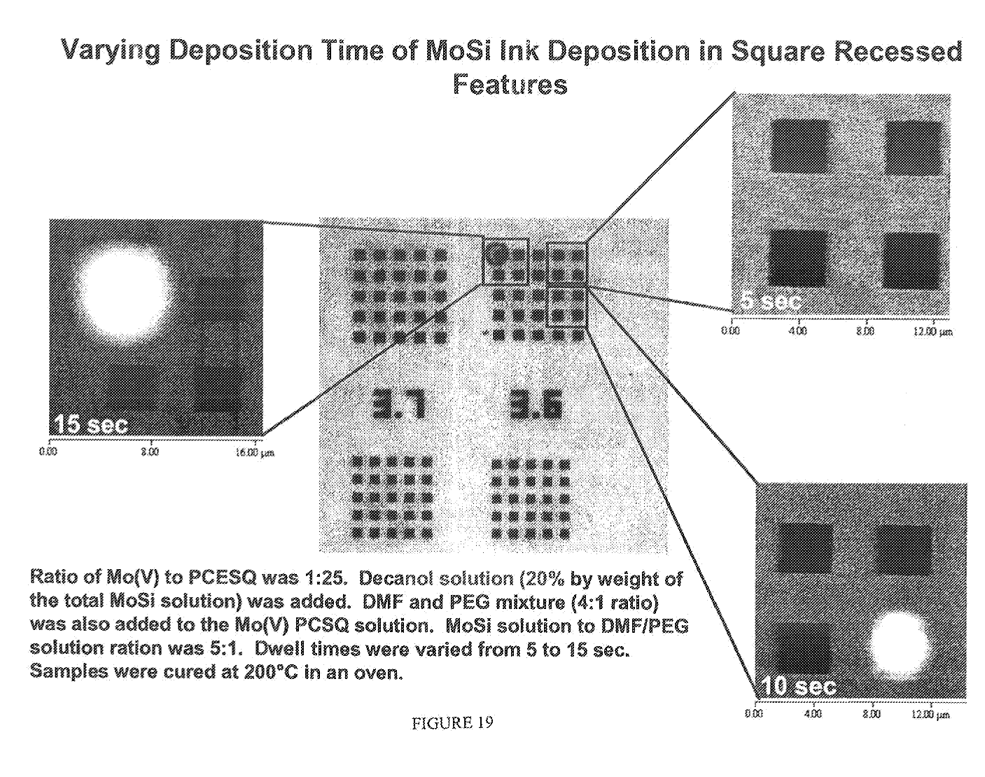

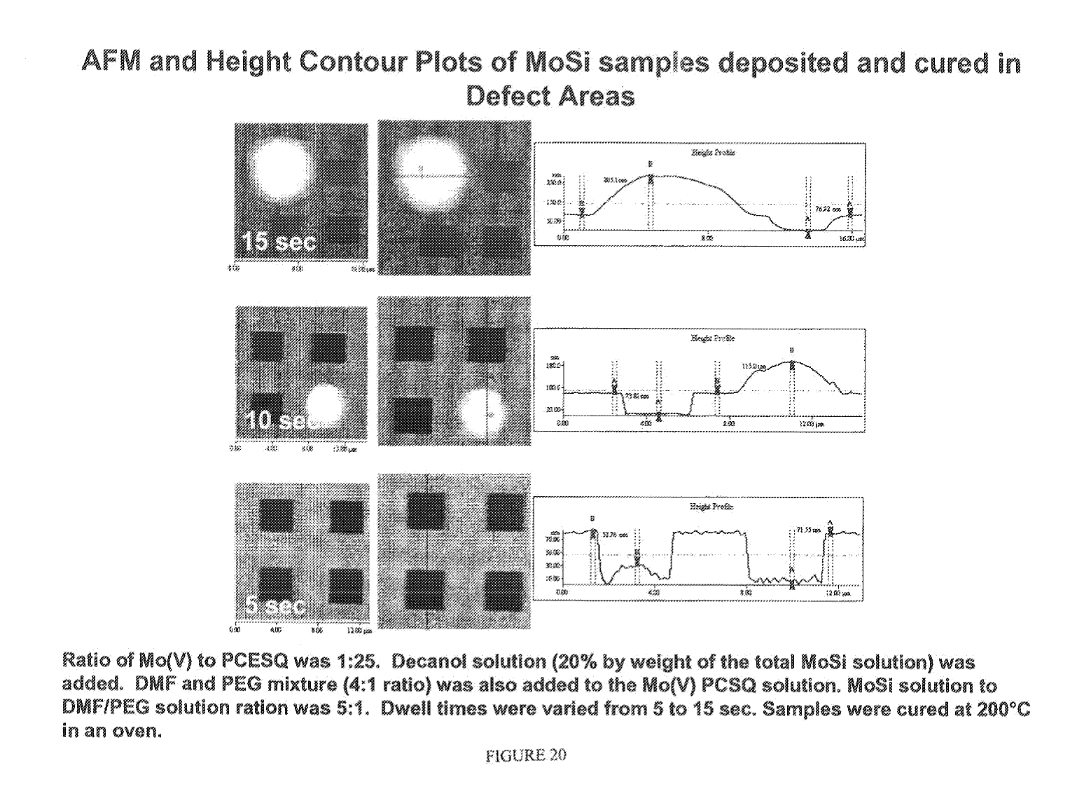

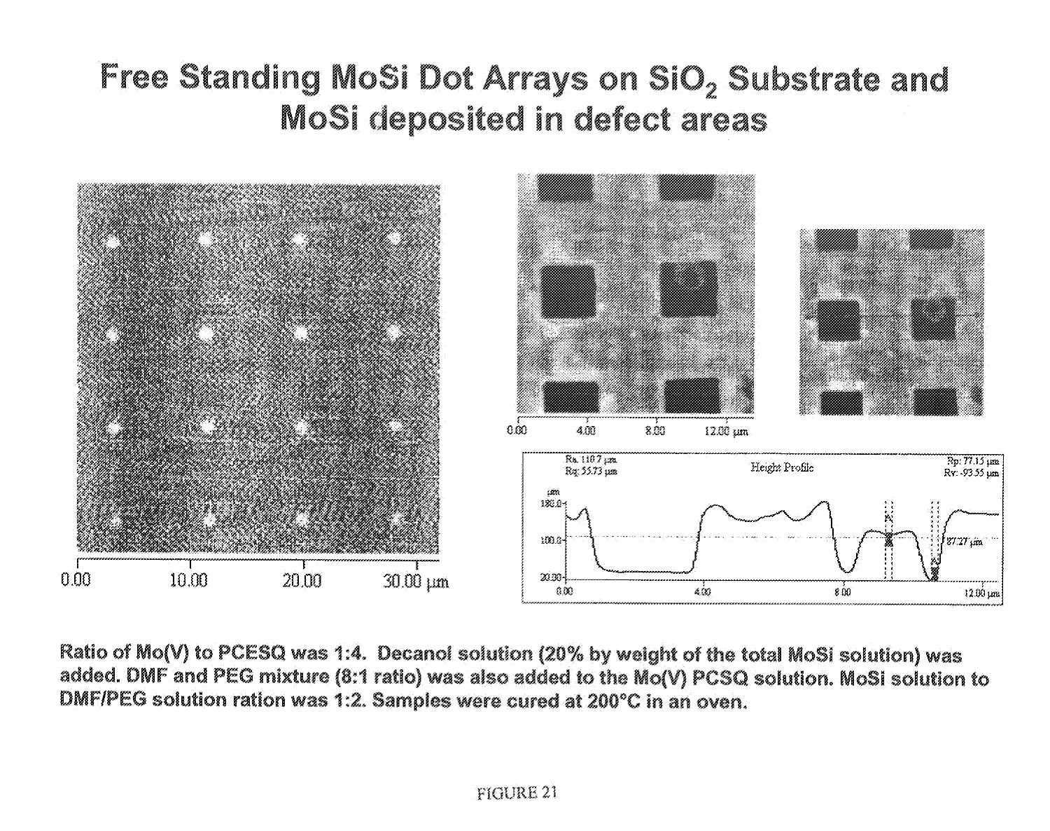

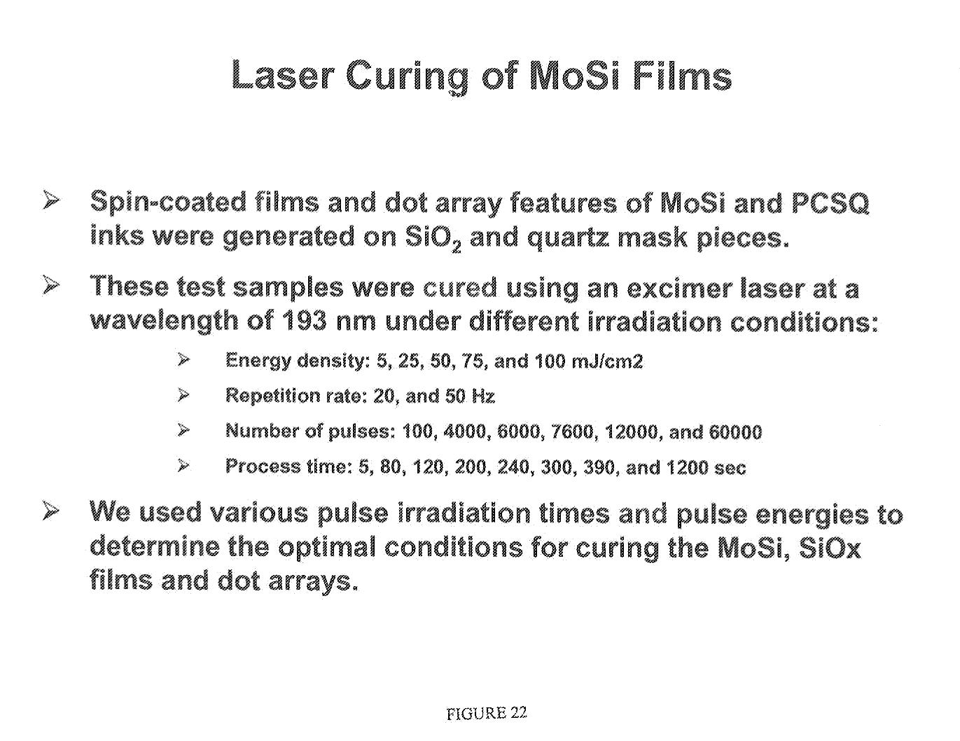

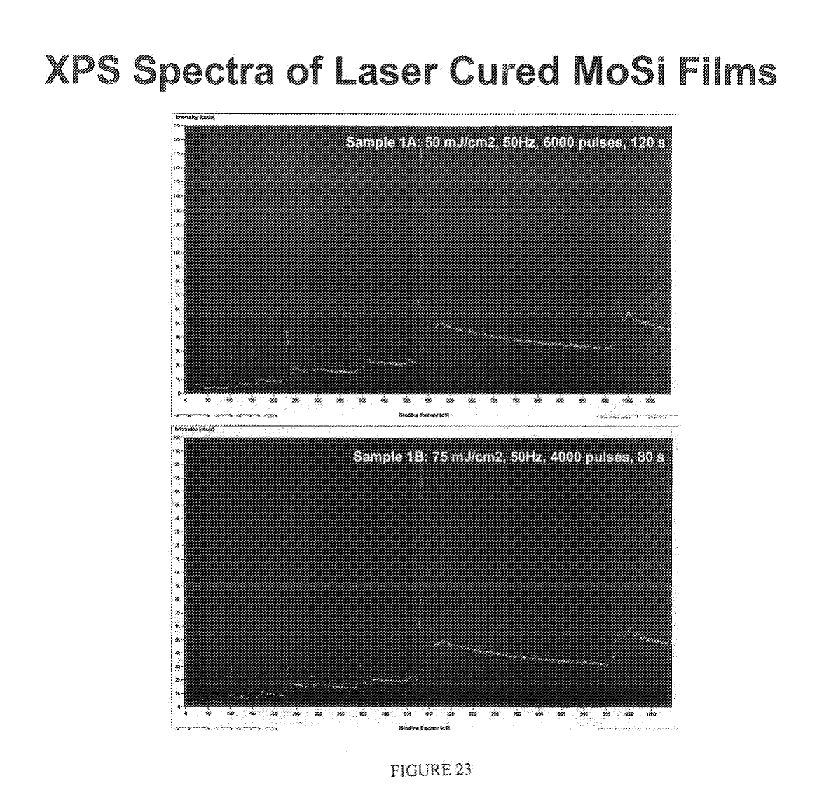

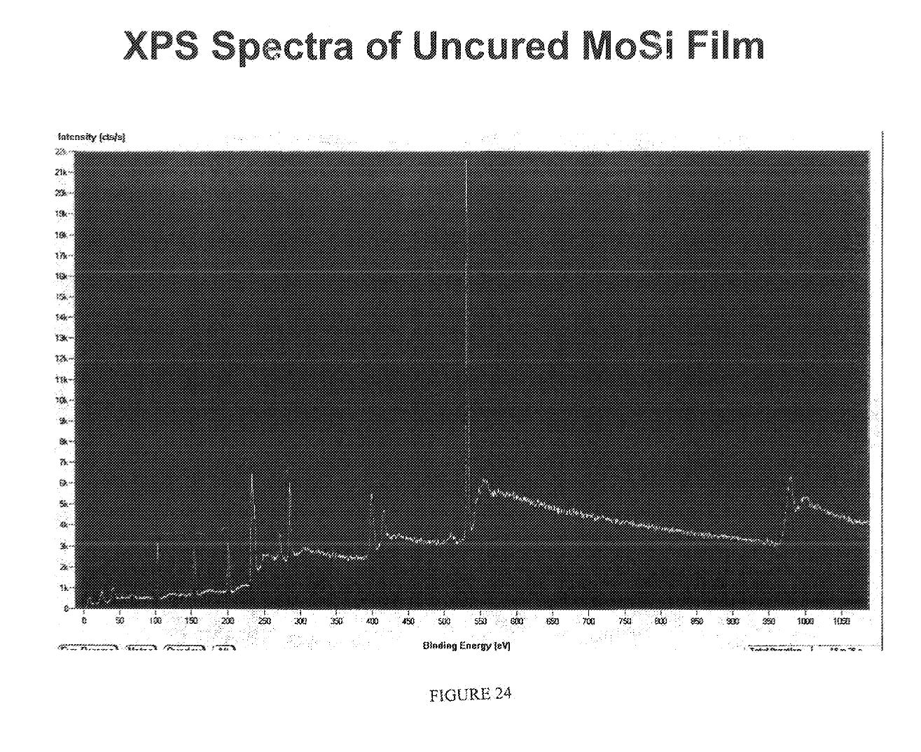

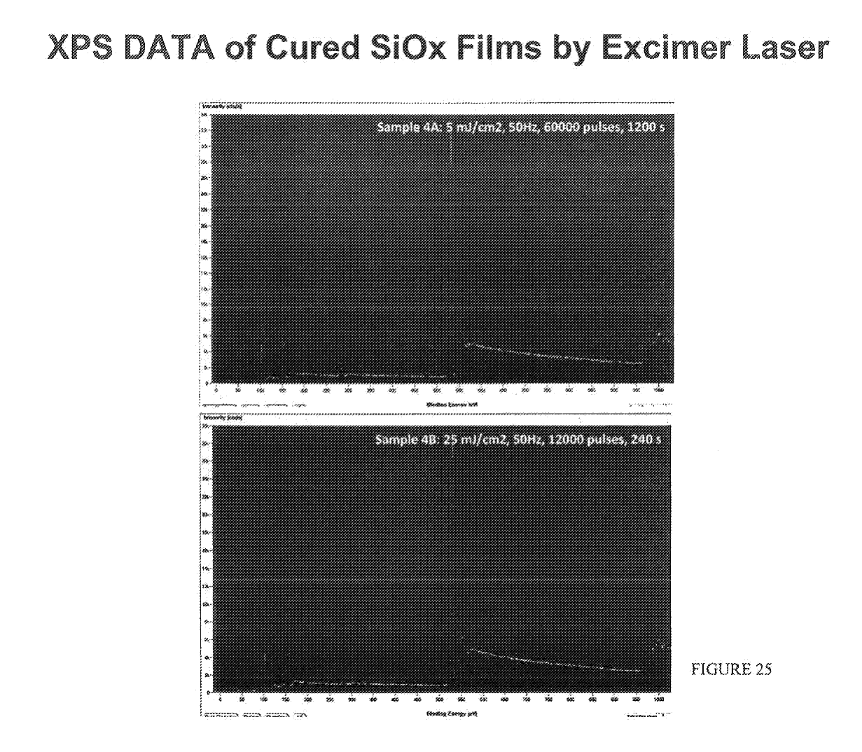

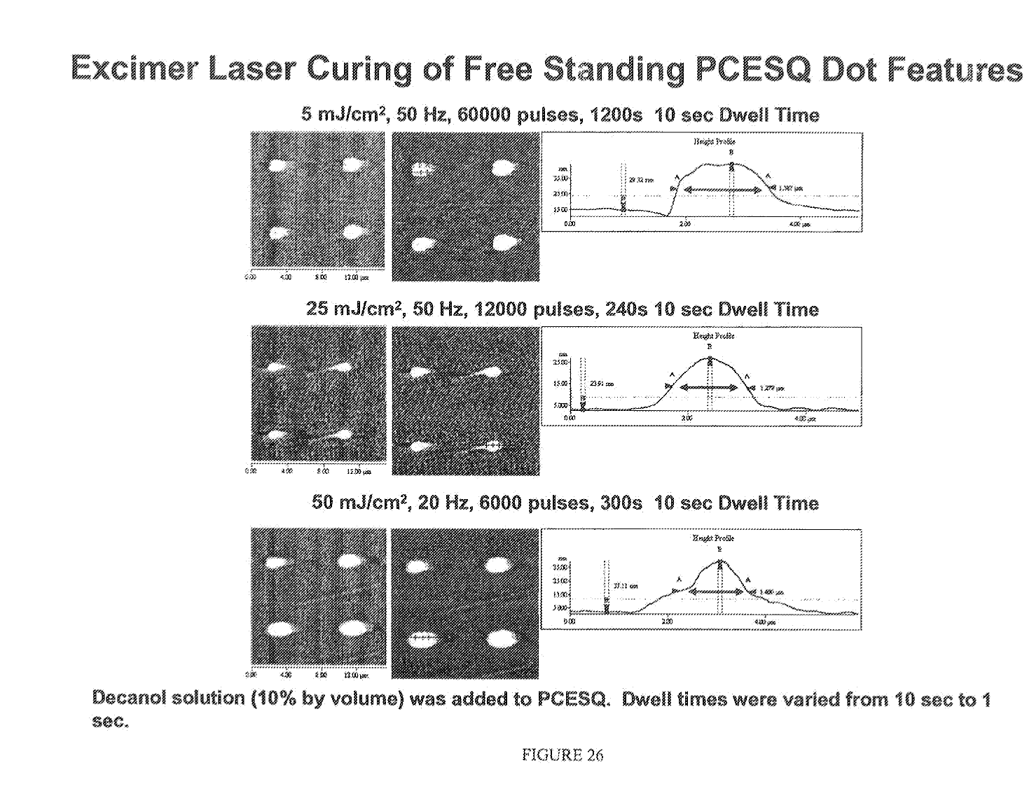

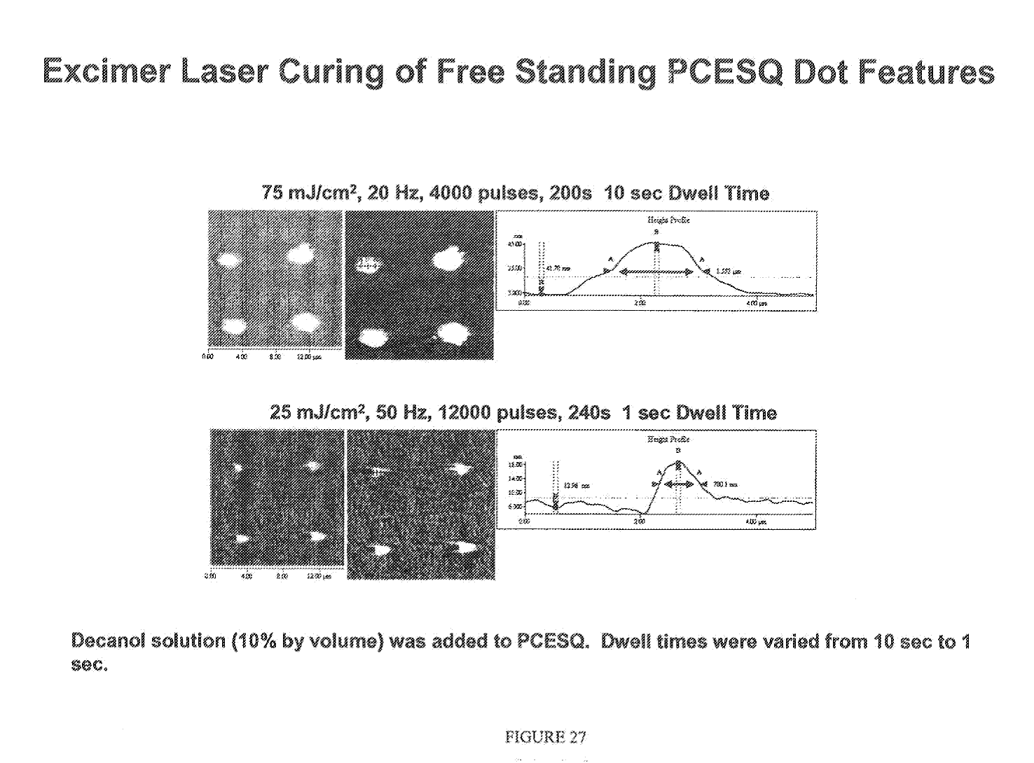

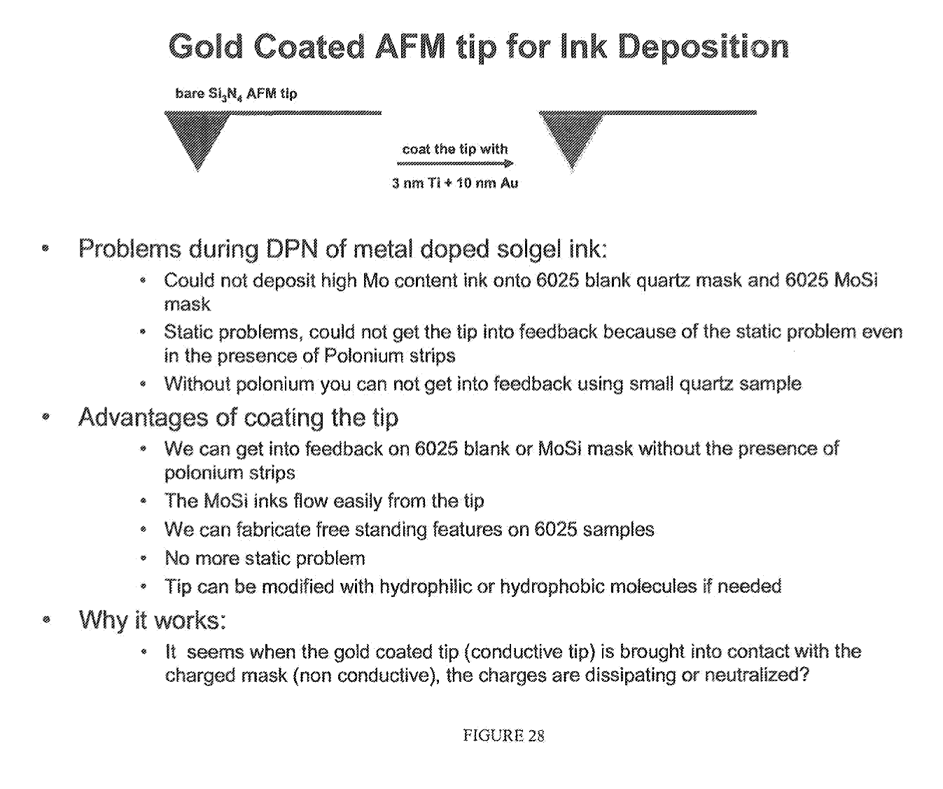

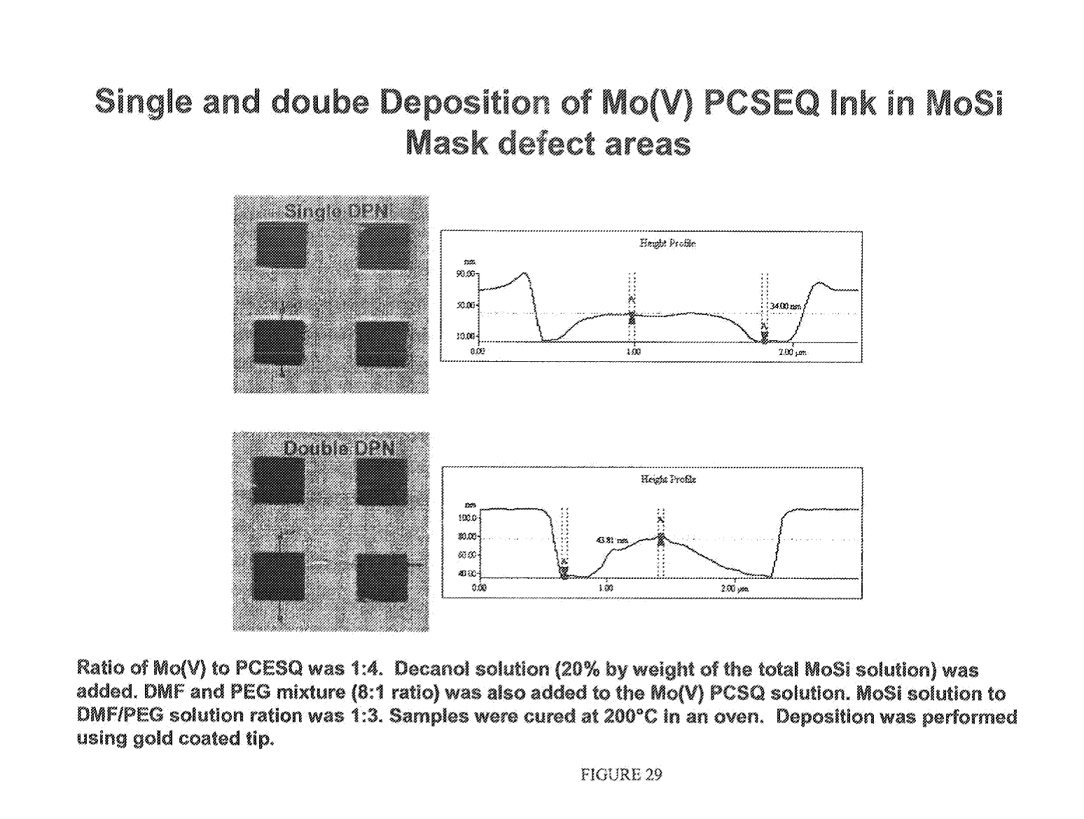

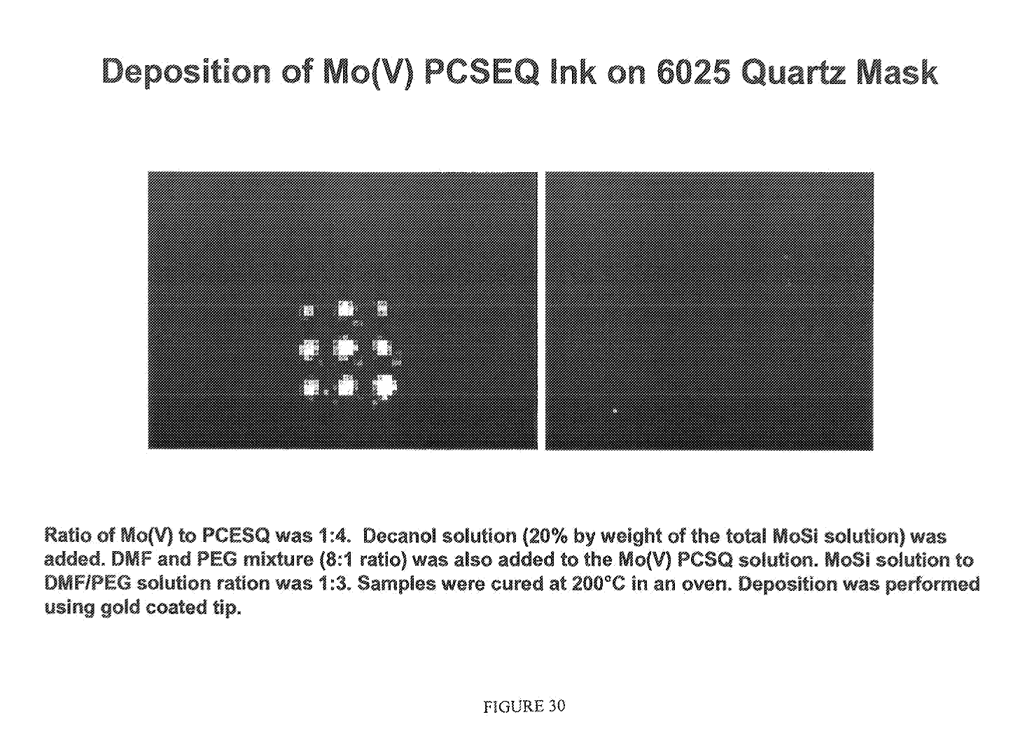

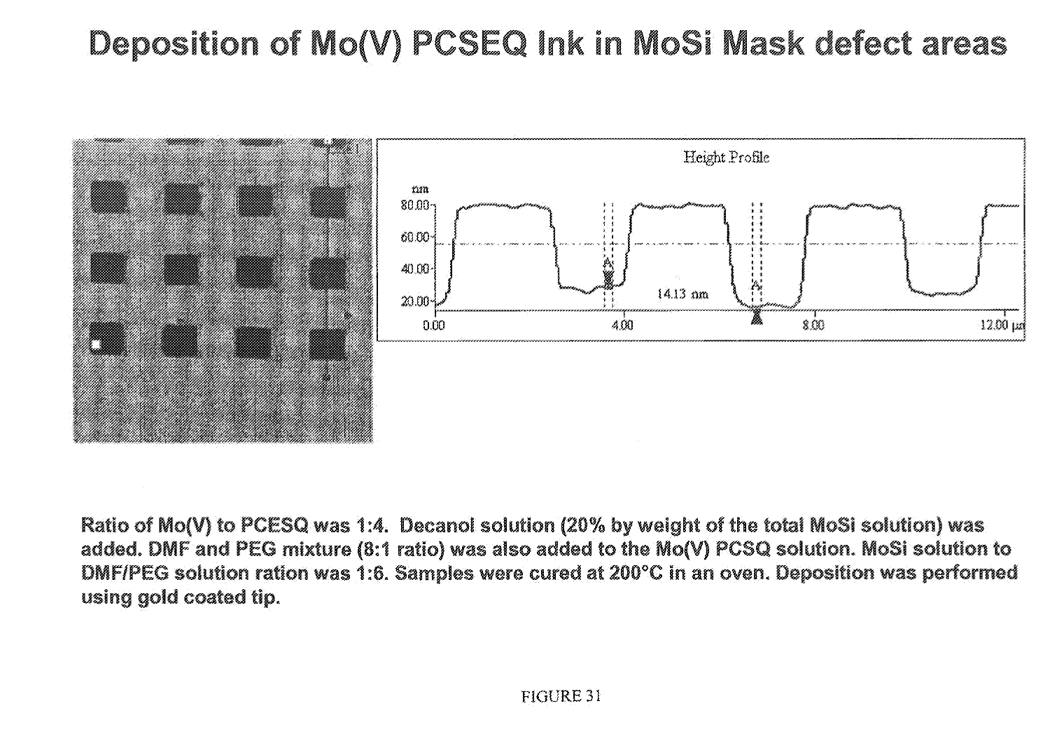

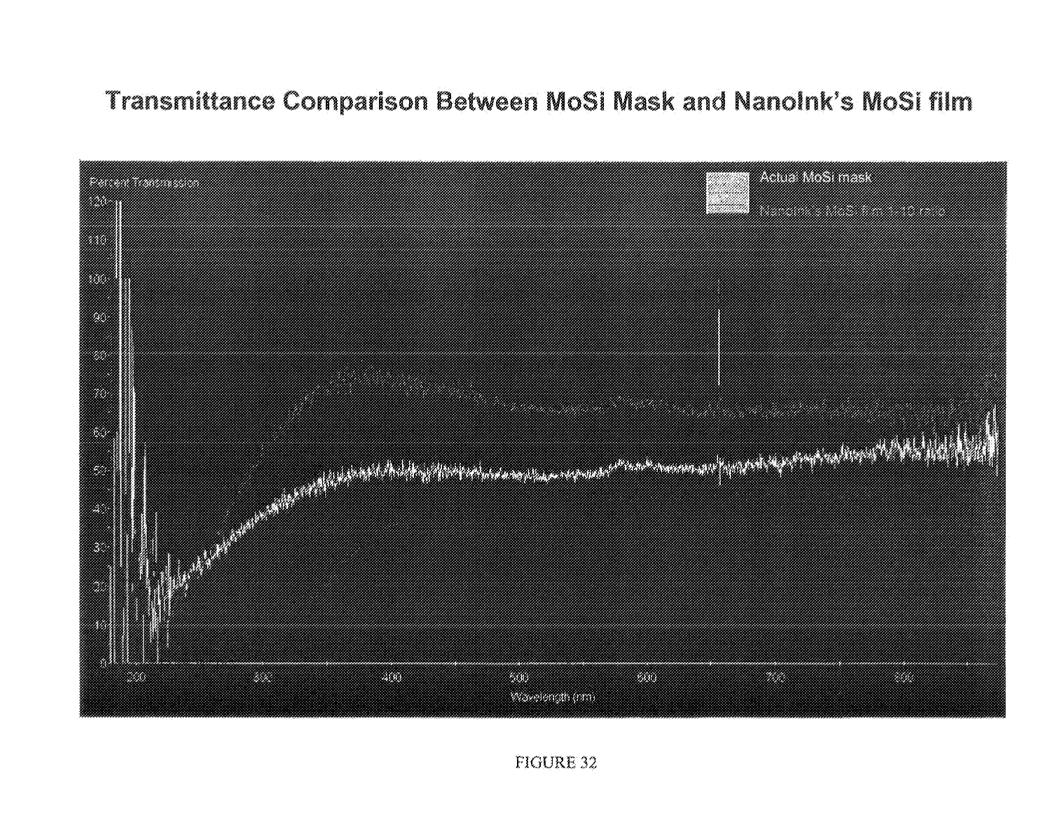

Additional working examples are shown in FIGS. 12-32.

In another example, MoSi thin film deposition on silicon and quartz substrates was carried out. Spin coating was used to prepare films with about 75 nm thickness. The MoSi film on the quartz material resembled in color an evaporated thin MoSi film. The solvent system DMF-PEG was replaced with acetone. Thickness and optical properties were measured by ellipsometry.

| | Ratio | | |
|---|---|---|---|
| | 1:2 | 1:1 | 2:1 |
| Thickness | 80 | 79 | 97 |
| Refractive index n | 1.72 | 1.72 | 1.82 |
| k | 0.5 | 0.66 | 0.83 |

In another example for making MoSi films on quartz masks inexpensively, MoSi thin films were made on quartz masks. 200 microliters of MoSi ink (1:10 ratio) were deposited onto a one inch square piece taken from a quartz mask. The spinning was carried out with spin coater for 5 sec at 500 rpm followed by 30 sec at 1500 rpm, curing of the piece between 250 and 350° C. for an hour, which formed a nice smooth film. For use of 400 microliters, a 300 nm film was formed. A target thickness is 100 nm.

Ellipsometry Measurements:

Ellipsometry is a non-destructive optical technique used for measuring thin layer thickness. It has useful capabilities for thin film characterization such as thickness, optical properties as well as band gap of the material. This technique is based on the measurement of the change in light polarization upon reflection from a sample surface; ellipsometry derives thin films thickness and optical properties (refractive index “n” and absorption coefficient “k”) with extreme accuracy. The spectroscopic capability allows for simultaneous determination of multiple parameters: for example multi-layer thickness and composition of thin film stacks. The ellipsometric raw data collected by the UVISEL a Phase Modulated Spectroscopic Ellipsometry (Jobin Yvon, Inc.) are converted into traditional ellipsometric data. The material properties such as thickness and optical constants n and k are deduced by fitting the experimental data to theoretical models build with the ellipsometry analysis software, Delta Psi 2. Validity and robustness of the model is double checked for every measured point by using a minimization algorithm based on Chi Square (χ2) method and by calculating a correlation matrix. The optical properties of the MoSi film shown in the figures represented herein are presented by blue line for n and red line for k at different wavelength from 190 to 820 nm.

The following experimental conditions were used for the MoSi thin films:

Spectral range of measurement 190 to 820 nm

Spot size: 1 mm diameter.

Integration time: 200 ms

What is claimed is:

1. A sol-gel composition formed by mixing:
a carrier solvent;
a silicon dioxide precursor comprising a silsesquioxane; and
a molybdenum precursor formed by evaporating a polar protic solvent out of a solution comprising the polar protic solvent and at least one of:
molybdenum(V) ethoxide;
molybdenum(VI) oxide Bis(2,4-pentanedionate); or
MoₓL_{y}, wherein L comprises an organic molecule or ligand.

2. The sol-gel composition of claim 1, wherein the silsesquioxane comprises poly(2-chloroethyl)silsesquioxane.

3. The sol-gel composition of claim 1, wherein the solution comprises molybdenum(V) ethoxide, and the sol-gel composition comprises a ratio of molybdenum atoms to silicon atoms of about 1:50 to about 50:1.

4. The sol-gel composition of claim 3, wherein the ratio is about 1:10 to about 10:1.

5. The sol-gel composition of claim 1, wherein the solution comprises molybdenum(VI) oxide Bis(2,4-pentanedionate), and the sol-gel composition comprises a ratio of molybdenum atoms to silicon atoms of about 1:50 to about 50:1.

6. The sol-gel composition of claim 5, wherein the ratio is about 1:10 to about 10:1.

7. The sol-gel composition of claim 1, wherein the polar protic solvent comprises ethanol.

8. The sol-gel composition of claim 1, wherein the carrier solvent comprises a weight percent of about 5% to about 30% of the silicon dioxide and molybdenum precursors, and the carrier solvent comprises an alcohol comprising a formula CₙH₍₂ₙ₊₂₎O, wherein 4≦n≦17.

9. The sol-gel composition of claim 8, wherein the weight percent is about 15% to about 25% and the carrier solvent comprises decanol.

10. The sol-gel composition of claim 1, further comprising a catalyst capable of lowering a curing temperature of the sol-gel composition.

11. The sol-gel composition of claim 10, wherein the catalyst is tetrabutylammonium fluoride.

12. The sol-gel composition of claim 1, further comprising at least one of dimethylformamide and polyethylene glycol.

13. The sol-gel composition of claim 12, comprising dimethylformamide and polyethylene glycol in a volumetric ratio of dimethylformamide to polyethylene glycol of about 1:10 to about 10:1.

14. The sol-gel composition of claim 1, further comprising acetone.

15. A solid formed by curing the sol-gel composition of claim 1, wherein the step of curing comprises at least one of:
heating the sol-gel composition at a temperature of about 100° C. to about 350° C.; or
irradiating the sol-gel composition with at least one of deep-UV, UV, UV-Visible, or Visible radiation.

16. The solid of claim 15, wherein the solid comprises a refractive index of about 1.15 to about 2.5 as measured at a wavelength of 193 nm.

17. The solid of claim 16, wherein the refractive index is about 1.5 to about 2.0.

18. The solid of claim 15, wherein the solid is disposed on at least a portion of a photomask.

19. The solid of claim 18, wherein the solid is disposed within at least a portion of a clear defect of the photomask.

20. A method for repairing a photomask, the method comprising:
providing a nanoscopic tip comprising an ink disposed on the tip end, wherein the ink comprises a sol-gel composition formed by mixing a carrier solvent and a silsesquioxane;
providing a photomask comprising a defective region;
contacting the tip with the photomask in the defective region, wherein ink is transferred from the tip to the region; and
forming a cured ink by at least one of:
heating the ink at a temperature of about 100° C. to about 350° C.; or
irradiating the ink with at least one of deep-UV, UV, UV-Visible, or Visible radiation.

21. The method according to claim 20, wherein the step of forming a cured ink comprises heating the ink at a temperature of about 100° C. to about 350° C.

22. The method according to claim 21, wherein the temperature is about 100° C. to about 250° C.

23. The method according to claim 21, wherein the temperature is provided from a resistive heater located on at least one of a scanning probe microscope tip or a scanning probe microscope cantilever.

24. The method according to claim 20, wherein the step of forming comprises exposing the ink to electromagnetic radiation comprising at least one of deep-UV, UV, UV-Visible, or Visible radiation.

25. The method according to claim 24, wherein the step of forming comprises exposing the ink to deep-UV radiation comprising a total dose of at least 100 mJ/cm².

26. The method according to claim 20, wherein:
the sol-gel composition is formed by mixing the carrier solvent, the silsesquioxane, and a molybdenum precursor; and
the molybdenum precursor is formed by evaporating a polar protic solvent out of a solution comprising the polar protic solvent and at least one of:
molybdenum(V) ethoxide;
molybdenum(VI) oxide Bis(2,4-pentanedionate); or
MoₓL_{y}, wherein L comprises an organic molecule or ligand.

27. The method according to claim 26, wherein the silsesquioxane comprises poly(2-chloroethyl)silsesquioxane.

28. The method of according to claim 27, wherein the solution comprises molybdenum(V) ethoxide.

29. The method of according to claim 27, wherein the solution comprises molybdenum(VI) oxide Bis(2,4-pentanedionate).

30. The method according to claim 26, wherein the sol-gel composition further comprises a catalyst capable of lowering a curing temperature of the ink.

31. The method according to claim 30, wherein the catalyst is tetrabutylammonium fluoride.

32. The method according to claim 26, wherein the cured ink comprises an alloy of molybdenum and silicon dioxide having a refractive index of about 1.15 to about 2.5 as measured at a wavelength of 193 nm.

33. The method according to claim 32, wherein the defective region comprises a depression that is at least 100 nm deep.

34. The method according to claim 20, wherein the tip comprises a scanning probe microscopic tip.

35. The method according to claim 34, wherein the tip comprises an atomic force microscope tip.

36. The method according to claim 35, wherein the tip end is coated with a polymer.

37. The method according to claim 35, wherein the tip end is coated with a conductive material.

38. The method according to claim 37, wherein the conductive material comprises gold.

39. A method of forming a MoSi nanostructure, the method comprising:
depositing a sol-gel composition onto a substrate, wherein the sol-gel composition is formed by mixing:
a carrier solvent;
a silicon dioxide precursor comprising a silsesquioxane; and
a molybdenum precursor formed by evaporating a polar protic solvent out of a solution comprising the polar protic solvent and at least one of:
molybdenum(V) ethoxide;
molybdenum(VI) oxide Bis(2,4-pentanedionate); or
MoₓL_{y}, wherein L comprises an organic molecule or ligand; and
thermally curing the sol-gel composition.

40. The method of claim 39, wherein:
the carrier solvent comprises an alcohol comprising a weight percent of about 5% to about 30% of the silicon dioxide and molybdenum precursors;
the polar protic solvent comprises ethanol; and
the silsesquioxane comprises poly(2-chloroethyl)silsesquioxane.

41. The method of claim 40, wherein the step of depositing comprises using a dip-pen nanolithography method to deposit the sol-gel composition from a tip of a scanning probe microscope.

42. The method of claim 40, wherein the step of depositing comprises spin coating the composition onto the substrate to form a thin film.

43. The method of claim 40, wherein the step of thermally curing comprises heating the composition at about 100° C. to about 350° C.

44. The method of claim 40, wherein the substrate comprises a photomask.

45. A method comprising:
providing a nanoscopic tip comprising an ink disposed on the tip end, wherein the ink comprises a sol-gel composition formed by mixing a carrier solvent and a silsesquioxane; and wherein the ink is adapted to have n and k substantially match a MoSi layer;
providing a photomask comprising a defective region;
contacting the tip with the photomask in the defective region, wherein ink is transferred from the tip to the region; and
forming a cured ink by at least one of:
heating the ink at a temperature of about 100° C. to about 350° C.; or
irradiating the ink with at least one of deep-UV, UV, UV-Visible, or Visible radiation.

46. A sol-gel composition formed by mixing:
a silicon dioxide precursor compound; and
a molybdenum precursor composition formed by evaporating a polar protic solvent out of a solution comprising the polar protic solvent and a molybdenum compound.
